(19) United States
(12) Patent Application Publication
(10) Pub. No.: US 2019/0292720 A1
(43) Pub. Date: Sep. 26, 2019

(54) Graphene-Mediated Metallization of Fibers, Yarns, and Fabrics

(71) Applicant: Nanotek Instruments, Inc., Dayton, OH (US)

(72) Inventors: Yi-jun Lin, Taoyuan City (TW); Shaio-yen Lee, New Taipei City (TW); Yao-de Jhong, Taipei City (TW); Aruna Zhamu, Springboro, OH (US); Bor Z. Jang, Centerville, OH (US)

(73) Assignee: Nanotek Instruments, Inc., Dayton, OH (US)

(21) Appl. No.: 15/926,474

(22) Filed: Mar. 20, 2018

(51) Int. Cl. D06M 11/83; D06M 11/74; D06M 15/356; D06M 17/06; D06M 17/10; C23C 14/14; C01B 32/194

(52) U.S. Cl. CPC D06M 11/83; D06M 11/74; D06M 15/3562; D06M 15/3566; D06M 2101/22; D06M 17/10; C23C 14/14; C01B 32/194; D06M 17/06

(57) ABSTRACT

Provided is surface-metalized fiber, yarn, or fabric comprising: (a) a fiber, yarn, or fabric having a surface; (b) a graphene layer having a thickness from 0.34 nm to 20 μm and comprising multiple graphene sheets and an optional conducive filler coated on or bonded to the surface, with or without using an adhesive resin, to form a graphene-coated fiber, yarn, or fabric; and (c) a metal layer comprising a plated metal deposited on the graphene-coated fiber, yarn, or fabric; wherein the graphene sheets contain single-layer or few-layer graphene sheets selected from a pristine graphene, graphene oxide, reduced graphene oxide, graphene fluoride, graphene chloride, graphene bromide, graphene iodide, hydrogenated graphene, nitrogenated graphene, doped graphene, chemically functionalized graphene, or a combination thereof. This film exhibits a high scratch resistance, strength, hardness, electrical conductivity, thermal conductivity, light reflectivity, gloss, etc.

### FIELD OF THE INVENTION

The present disclosure relates generally to the field of surface metallization of fibers, bundles/tows of multiple fibers (e.g. yarns), and fabrics and, more particularly, to graphene-mediated metal-plated fibers/yarns/fabrics and a process for producing same.

### BACKGROUND OF THE INVENTION

Metallized plastics are commonly used for decorative purposes. For instance, the surfaces of plastics, such as acrylonitrile-butadiene-styrene (ABS) and ABS-Polycarbonate blends, are metallized for use in sanitary fittings, automobile accessories, furniture, hardware, jewelries, and buttons/knobs. These articles of manufacture may be metallized to impart an attractive appearance to the article surfaces.

In addition, plastics, rubbers, and polymer matrix composites (e.g. fiber-reinforced or additive-filled thermoplastic, thermoset, and rubber matrix composites) can also be metallized for functional purposes. For instance, metallization of plastics-based electronic components may be carried out for the purpose of shielding against electromagnetic interference (EMI). Additionally, the surface properties of polymeric components can be altered in a controlled manner through metallic coating.

Articles made from an electrically nonconductive polymer (e.g. a fiber/yarn/fabric and film of a plastic, rubber, polymer matrix composite, etc.) can be metallized by an electroless metallization process. In a typical process, the article is first cleaned and etched, then treated with a noble metal (e.g. palladium) and finally metallized in a metallizing solution. The etching step typically involves the use of chromic acid or chromosulfuric acid. The etching step serves to make the surface of the article receptive to the subsequent metallization through improved surface wettability by the respective solutions in the subsequent treatment steps and to make the ultimately deposited metal being well-adhered to the polymer surface.

In the etching step, the surface of a polymer article is etched using chromosulfuric acid to form surface micro-caverns in which metal is deposited and adhered. After the etching step, the polymer component surface is activated by means of an activating agent (or activator), typically comprising a noble metal, and then metallized using electroless plating. Subsequently, a thicker metal layer can be deposited electrolytically.

Chromosulfuric acid-based etching solutions are toxic and should therefore be replaced where possible. For instance, the etching solutions based on chromosulfuric acid may be replaced with those comprising permanganate salts. The use of permanganates in an alkaline medium for metallization of circuit boards as a carrier of electronic circuits has long been established. Since the hexavalent state (manganate) which arises in the oxidation is water-soluble and has sufficient stability under alkaline conditions, the manganate, similarly to trivalent chromium, can be oxidized electrolytically back to the original oxidizing agent, in this case the permanganate. For the metallization of ABS plastics, a solution of alkaline permanganate has been found to be unsuitable since it was not possible in this way to obtain a sufficient adhesion strength between the metal layer and plastic substrate. This adhesion strength is determined in the “peel test” and should have at least a value of 0.4 N/mm.

As an alternative to chromosulfuric acid, WO 2009/023628 A2 proposes the use of strongly acidic solutions comprising an alkali metal permanganate salt. The solution contains about 20 g/l alkali metal permanganate salt in 40-85% by weight phosphoric acid. Such solutions form colloidal manganese(IV) species which are difficult to remove. Further, it is also difficult for colloids to form a coating of adequate quality. To solve the problem, WO 2009/023628 A2 proposes the use of manganese(VII) sources which do not contain any alkali metal or alkaline earth metal ions. However, the preparation of such manganese(VII) sources is costly and inconvenient.

Thus, there is an urgent need to conduct industrial scale metallization of a fiber, yarn, or fabric surface without using chromic acid, chromosulfuric acid or an alkali metal permanganate salt.

Another major issue of the prior art metallization process is the notion that, after the etching step, the polymer component surface must be activated by means of an activating agent, which typically comprises a noble metal (e.g. palladium). The noble metals are known to be rare and expensive. In an alternative process [L. Naruskevicius, et al. “Process for metallizing a plastic surface,” U.S. Pat. No. 6,712,948 (Mar. 30, 2004)], the chemically etched plastic surface is treated with a metal salt solution, containing cobalt salt, silver salt, tin salt, or lead salt. However, the activated plastic surface must be further treated with a sulfide solution. The entire process is slow, tedious, and expensive.

Thus, there is a further urgent need to conduct industrial scale metallization of fiber, yarn, or fabric surfaces without using an expensive noble metal in an activating agent or even without the activating step if all possible. The fiber, yarn, or fabric to be metallized is not limited to polymer fiber-based; they can be based on glass fibers, ceramic fibers, carbon fibers, polymer fibers (plastic, elastomeric, and composite fibers), etc.

### SUMMARY OF THE INVENTION

The present disclosure provides a surface-metalized fiber, yarn, or fabric comprising: (a) a fiber, yarn, or fabric having a surface; (b) a graphene layer having a thickness from 0.34 nm to 20 μm and comprising multiple graphene sheets and an optional conducive filler coated on or bonded to the surface, with or without using an adhesive resin, to form a graphene-coated fiber, yarn, or fabric; and (c) a metal layer comprising a plated metal deposited on the graphene-coated fiber, yarn, or fabric; wherein the graphene sheets contain single-layer or few-layer graphene sheets selected from a pristine graphene, graphene oxide, reduced graphene oxide, graphene fluoride, graphene chloride, graphene bromide, graphene iodide, hydrogenated graphene, nitrogenated graphene, doped graphene, chemically functionalized graphene, or a combination thereof. This film exhibits a high scratch resistance, strength, hardness, electrical conductivity, thermal conductivity, light reflectivity, gloss, etc.

A yarn or fiber tow is composed of multiple fibers that are aggregated together, with or without a twist and with or without a binder. A fabric is composed of multiple yarns or fiber tows that are combined together with weaving (woven fabric) or without weaving (e.g., nonwoven fabric) and with or without a binder. The fiber may be selected from a polymer fiber, glass fiber, carbon fiber, ceramic fiber, or composite fiber. The fiber yarn or fiber fabric may contain one type or multiple types of fibers having a fiber selected from a polymer fiber, glass fiber, carbon fiber, ceramic fiber, composite fiber, or a combination thereof. A fiber typically has a circular cross-section; however, it can assume various different shapes. The fiber can be a continuous fiber, long fiber, or short fiber (e.g. chopped fiber). The fiber diameter can range from 10 nm to 10 mm, more typically from 100 nm to 1 mm, and most typically from 1 μm to 100 μm. A fiber or a yarn has a surface (exterior surface), but a fabric can have two primary surfaces. In certain embodiments, both primary surfaces are metallized.

Thus, in the disclosed surface-metalized fiber, yarn, or fabric, the surface (or two surfaces) is coated with or bonded to a graphene layer having a thickness from 0.34 nm to 20 μm and comprising multiple graphene sheets and an optional conducive filler (not always desirable). Also, a metal layer comprising a plated metal is deposited on the graphene layer.

With such a high-quality metallic coating mediated by graphene sheets, polymer fibers, yarns, or fabrics can take on a luxurious chrome look and exhibit superior abrasion resistance, barrier properties (e.g. for fabrics against permeation of water vapor, oxygen, etc.), heat radiation reflective properties, corrosion resistance, strength, and hardness. Hence, they can be used in design elements for automobiles, bikes and motorcycles, electrical appliances, electronic devices, kitchens and bathrooms. For example, in vehicles, radiator grills, mirror caps, door handles and trim are some items with such a finish. In electronic devices and electrical appliance, examples of metallized polymer components include push buttons and covers for wi-fi devices, sound recording or playback equipment, cell phones and coffee machines, LED lamp housing, EMI shielding coating layer for electronic equipment, metallized housings for telecommunications devices (e.g. smart phones, smart watches, wearable devices), laptop computers, tablet computers, telescope parts, susceptor for cooking in microwave ovens (e.g. a microwave popcorn bag).

Other uses of metallized polymer fiber fabrics include diffusion barrier in the food packaging (e.g. candy wrapper), antistatic bag, protective clothing (high-energy radiation shield, heat shield from fuel fires, radiation heat reflector, etc.), aluminized blanket to keep patients warm, children's toys, solar control window fabric, etc.

The present disclosure also provides an apparatus that can be used to produce the surface-metallized fiber, yarn, or fabric. The apparatus for manufacturing a surface-metalized fiber, yarn, or fabric may comprise: (a) a fiber, yarn, or fabric feeder device (e.g. a spool or a feeder roller) that provides (pays out) a continuous fiber, yarn, or fabric; (b) a graphene deposition chamber (e.g. a graphene dispersion bath) that accommodates a graphene dispersion comprising multiple graphene sheets and an optional conducive filler dispersed in a first liquid medium and an optional adhesive resin dissolved in the first liquid medium, wherein the graphene deposition chamber is operated to deposit the graphene sheets and optional conductive filler to a surface of the continuous fiber, yarn, or fabric for forming a graphene-coated fiber, yarn, or fabric; (c) a metallization chamber (e.g. a metal plating bath), in a working relationship with the graphene deposition chamber, which accommodates a plating solution for plating a layer of a desired metal on the graphene-coated fiber, yarn, or fabric to obtain the surface-metalized fiber, yarn, or fabric; and (d) a winding roller (receiver roller) to wind up the surface-metallized fiber, yarn, or fabric continuously, wherein the multiple graphene sheets contain single-layer or few-layer graphene sheets selected from a pristine graphene material having essentially zero % of non-carbon elements, or a non-pristine graphene material having 0.001% to 25% by weight of non-carbon elements wherein said non-pristine graphene is selected from graphene oxide, reduced graphene oxide, graphene fluoride, graphene chloride, graphene bromide, graphene iodide, hydrogenated graphene, nitrogenated graphene, doped graphene, chemically functionalized graphene, or a combination thereof.

The apparatus may further comprise a series of guiding rollers or rods that control the movement directions of the fiber, yarn, or fabric so that the fiber, yarn, or fabric may be brought into contact with the graphene dispersion (e.g. for dipping the fiber, yarn, or fabric into the graphene dispersion bath and then retreating the fiber, yarn, or fabric from this bath) for producing a graphene-coated fiber, yarn, or fabric and the graphene-coated fiber, yarn, or fabric be brought in contact with the plating solution (e.g. for dipping the graphene-coated fiber, yarn, or fabric into the plating solution in the metal plating bath and then retreating the metal-plated graphene-coated fiber, yarn, or fabric from this plating bath) to obtain the desired surface-metalized fiber, yarn, or fabric.

The apparatus may further comprise a drying, heating, or curing provision in a working relation with the graphene deposition chamber (e.g. above the graphene dispersion bath) for partially or completely removing the first liquid medium from the graphene-coated fiber, yarn, or fabric and/or for polymerizing or curing the adhesive resin (if present) for producing the graphene-coated fiber, yarn, or fabric containing multiple graphene sheets that are bonded to thee surface.

In the apparatus, the plating solution may contain a chemical plating solution, an electrochemical plating solution, or an electrophoretic solution. Preferably, the plating solution contains a chemical plating solution comprising a metal salt dissolved in water, aqueous solution, or an organic solvent. The metal salt (e.g. CuSO₄ or NiNO₃) contains a metal ion (e.g. Cu⁺² or Ni⁺²) to be deposited onto a fiber, yarn, or fabric surface.

In certain embodiments, the conductive filler is selected from metal nanowires, carbon fibers, carbon nanofibers, carbon nanotubes, carbon-coated fibers, conductive polymer fibers, nanofibers or nanowires of SnO₂, ZnO₂, In₂O₃, or indium-tin oxide (ITO), a conductive polymer not in a fiber form, or a combination thereof. The metal nanowires are preferably selected from nanowires of silver (Ag), gold (Au), copper (Cu), platinum (Pt), zinc (Zn), cadmium (Cd), cobalt (Co), molybdenum (Mo), aluminum (Al), or a combination thereof. The conductive polymer is preferably selected from the group consisting of polydiacetylene, polyacetylene (PAc), polypyrrole (PPy), polyaniline (PAni), polythiophene (PTh), polyisothionaphthene (PITN), polyheteroarylenvinylene (PArV), in which the heteroarylene group can be the thiophene, furan or pyrrole, poly-p-phenylene (PpP), polyphthalocyanine (PPhc) and the like, and their derivatives, and combinations thereof.

The chemical functional groups attached to graphene sheets are preferably those that make the graphene exhibit a negative Zeta potential in an intended dispersion medium (e.g. water, a salt-containing water solution, an organic solvent, etc.).

In some embodiments, the chemical functional group is selected from alkyl or aryl silane, alkyl or aralkyl group, hydroxyl group, carboxyl group, amine group, sulfonate group (—SO₃H), aldehydic group, quinoidal, fluorocarbon, or a combination thereof.

Alternatively, the functional group contains a derivative of an azide compound selected from the group consisting of 2-Azidoethanol, 3-Azidopropan-1-amine, 4-(2-Azidoethoxy)-4-oxobutanoic acid, 2-Azidoethyl-2-bromo-2-methylpropanoate, chlorocarbonate, azidocarbonate, dichlorocarbene, carbene, aryne, nitrene, (R−)-oxycarbonyl nitrenes, where R=any one of the following groups,

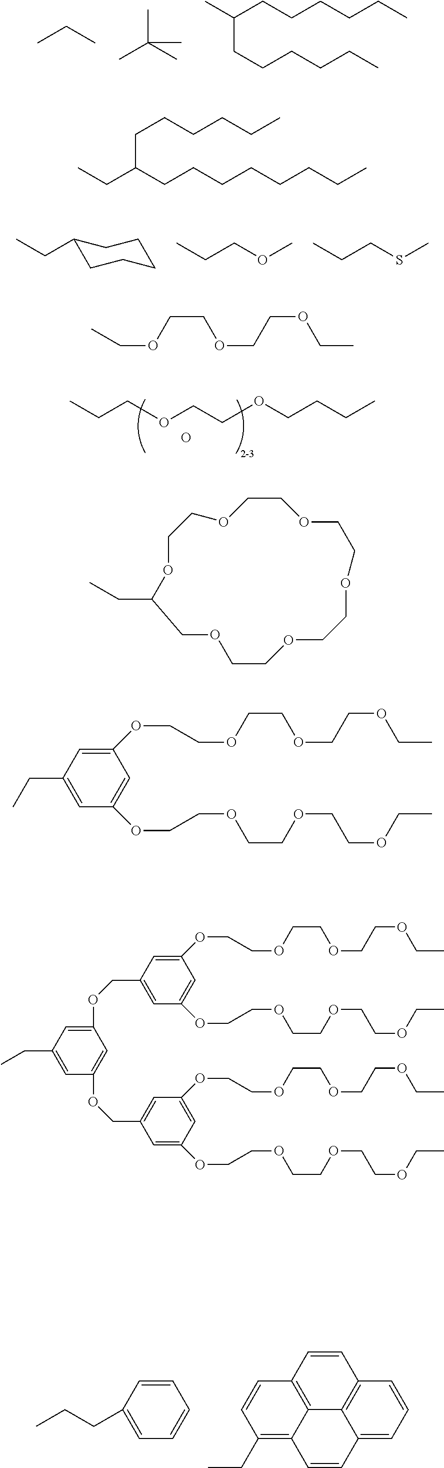

and combinations thereof.

In certain embodiments, the functional group is selected from the group consisting of hydroxyl, peroxide, ether, keto, and aldehyde. In certain embodiments, the functionalizing agent contains a functional group selected from the group consisting of SO₃H, COOH, NH₂, OH, R′CHOH, CHO, CN, COCl, halide, COSH, SH, COOR′, SR′, SiR′₃, Si(—OR′—)_{y}R′₃-y, Si(—O—SiR′₂—)OR′, R″, Li, AlR′₂, Hg—X, TlZ₂ and Mg—X; wherein y is an integer equal to or less than 3, R′ is hydrogen, alkyl, aryl, cycloalkyl, or aralkyl, cycloaryl, or poly(alkylether), R″ is fluoroalkyl, fluoroaryl, fluorocycloalkyl, fluoroaralkyl or cycloaryl, X is halide, and Z is carboxylate or trifluoroacetate, and combinations thereof.

The functional group may be selected from the group consisting of amidoamines, polyamides, aliphatic amines, modified aliphatic amines, cycloaliphatic amines, aromatic amines, anhydrides, ketimines, diethylenetriamine (DETA), triethylene-tetramine (TETA), tetraethylene-pentamine (TEPA), polyethylene polyamine, polyamine epoxy adduct, phenolic hardener, non-brominated curing agent, non-amine curatives, and combinations thereof.

In some embodiments, the functional group may be selected from OY, NHY, O═C—OY, P═C—NR′Y, O═C—SY, O═C—Y, —CR′1-OY, N′Y or C′Y, and Y is a functional group of a protein, a peptide, an amino acid, an enzyme, an antibody, a nucleotide, an oligonucleotide, an antigen, or an enzyme substrate, enzyme inhibitor or the transition state analog of an enzyme substrate or is selected from R′—OH, R′—NR′₂, R′SH, R′CHO, R′CN, R′X, R′N⁺(R′)₃X⁻, R′SiR′₃, R′Si(—OR′—)_{y}R′_{3-y}, R′Si(—O—SiR′₂—)OR′, R′—R″, R′—N—CO, (C₂H₄O—)_{w}H, (—C₃H₆O—)_{w}H, (—C₂H₄O)_{w}—R′, (C₃H₆O)_{w}—R′, R′, and w is an integer greater than one and less than 200.

In certain embodiments, the first layer (graphene layer) contains an adhesive resin that chemically bonds the graphene sheets and the conductive filler to a surface of the fiber, yarn, or fabric. In certain alternative embodiments, the graphene sheets contain a non-pristine graphene material having a content of non-carbon elements from 0.01% to 20% by weight and the non-carbon elements include an element selected from oxygen, fluorine, chlorine, bromine, iodine, nitrogen, hydrogen, or boron. These graphene sheets may be further chemically functionalized to exhibit a negative Zeta potential.

The fiber, yarn, or fabric may contain a plastic, a rubber, a thermoplastic elastomer, a polymer matrix composite, a rubber matrix composite, or a combination thereof. In certain embodiments, the fiber, yarn, or fabric contains a fiber of thermoplastic, a thermoset resin, an interpenetrating network, a rubber, a thermoplastic elastomer, a natural polymer, or a combination thereof. In certain preferred embodiments, the polymer film contains a plastic selected from acrylonitrile-butadiene-styrene copolymer (ABS), styrene-acrylonitrile copolymer (SAN), polycarbonate, polyamide or nylon, polystyrene, high-impact polystyrene (HIPS), polyacrylate, polyethylene, polypropylene, polyacetal, polyester, polyether, polyether sulfone, poly ether ether ketone, poly sulfone, polyphenylene oxide (PPO), polyvinyl chloride (PVC), polyimide, polyamide imide, polyurethane, polyurea, or a combination thereof.

In the surface-metalized fiber, yam, or fabric, the plated metal is preferably selected from copper, nickel, aluminum, chromium, tin, zinc, titanium, silver, gold, an alloy thereof, or a combination thereof. There is no limitation on the type of metals that can be plated.

Although not necessary and not desirable, the graphene sheets may be further decorated with nanoscaled particles or coating (having a diameter or thickness from 0.5 nm to 100 nm) of a catalytic metal selected from cobalt, nickel, copper, iron, manganese, tin, zinc, lead, bismuth, silver, gold, palladium, platinum, an alloy thereof, or a combination thereof, and wherein the catalytic metal is different in chemical composition than the plated metal.

In certain embodiments, the fiber, yarn, or fabric surface, prior to being deposited with the layer of graphene sheets and a conductive filler, contains only small openings or pores having a diameter or a depth <0.1 μm.

In certain embodiments, the multiple graphene sheets and the conductive filler are bonded to the fiber, yarn, or fabric surface with an adhesive resin having an adhesive-to-graphene weight ratio from 1/5000 to 1/10, preferably from 1/1000 to 1/100.

The disclosure also provides a process for producing a surface-metalized fiber, yarn, or fabric. In certain preferred embodiments, the process comprises:
(a) Feeding a continuous fiber, yam, or fabric from a feeder roller or spool into a graphene deposition chamber, wherein the graphene deposition chamber contains therein a graphene dispersion comprising multiple graphene sheets and an optional conducive filler dispersed in a first liquid medium and an optional adhesive resin dissolved in this first liquid medium;
(b) Operating the graphene deposition chamber to deposit the graphene sheets and optional conductive filler to a surface of the fiber, yarn, or fabric for forming a graphene-coated fiber, yarn, or fabric;
(c) Moving the graphene-coated fiber, yarn, or fabric into a metallization chamber which accommodates a plating solution therein for plating a layer of a desired metal onto the graphene-coated fiber, yarn, or fabric to obtain a surface-metalized fiber, yam, or fabric; and
(d) Operating a winding roller to collect the surface-metalized fiber, yarn, or fabric; wherein the multiple graphene sheets contain single-layer or few-layer graphene sheets selected from a pristine graphene material having essentially zero % of non-carbon elements, or a non-pristine graphene material having 0.001% to 25% by weight of non-carbon elements wherein said non-pristine graphene is selected from graphene oxide, reduced graphene oxide, graphene fluoride, graphene chloride, graphene bromide, graphene iodide, hydrogenated graphene, nitrogenated graphene, doped graphene, chemically functionalized graphene, or a combination thereof. One or both primary surfaces of a fabric may be metallized in this process. The plating solution may contain a chemical plating solution, an electrochemical plating solution, or an electrophoretic solution.

The process may further comprise operating a drying, heating, or curing means to partially or completely remove the first liquid medium from the graphene-coated fiber, yarn, or fabric and/or to polymerize or cure the optional adhesive resin for producing the graphene-coated fiber, yarn, or fabric containing the multiple graphene sheets that are bonded to a surface of the fiber, yarn, or fabric (or both surfaces of the fabric).

Preferably, the process further contains a step of chemically functionalizing the graphene sheets (pristine graphene, graphene oxide, reduced graphene oxide, fluorinated graphene, nitrogenated graphene, etc.) so that the graphene sheets in an intended dispersion medium exhibit a negative Zeta potential, preferably from −55 mV to −0.1 mV.

In certain embodiments, the process further comprises, prior to step (a), a step of subjecting the fiber, yarn, or fabric surface to a grinding treatment, an etching treatment, or a combination thereof. In some embodiments, step (a) includes a step of subjecting the fiber, yarn, or fabric surface to an etching treatment using an etchant selected from an acid, an oxidizer, a metal salt, or a combination thereof.

Preferably, the process further comprises, prior to step (a), a step of subjecting the fiber, yam, or fabric surface to an etching treatment without using chromic acid or chromosulfuric acid. More preferably, the method further comprises, prior to step (a), a step of subjecting the fiber, yarn, or fabric surface to an etching treatment using an etchant selected from an acid, an oxidizer, a metal salt, or a combination thereof under a mild etching condition wherein etching is conducted at a sufficiently low temperature for a sufficiently short period of time so as not to create micro-caverns having an average size greater than 0.1 μm.

Although unnecessary, the graphene sheets may be further decorated with nanoscaled particles or coating of a catalytic metal, having a diameter or thickness from 0.5 nm to 100 nm, selected from cobalt, nickel, copper, iron, manganese, tin, zinc, lead, bismuth, silver, gold, palladium, platinum, an alloy thereof, or a combination thereof.

In certain embodiments, step (a) and step (b) include immersing or dipping the fiber, yam, or fabric in the dispersion and then removing the fiber, yam, or fabric from the dispersion to effect deposition of graphene sheets and the conductive filler onto one or both primary surfaces of the surface-treated fiber, yam, or fabric wherein the graphene sheets and the conductive filler (if present) are bonded to the surface to form a layer of bonded graphene sheets and conductive filler. Alternatively, one may simply spray graphene dispersion or graphene/conductive filler mixture dispersion over the fiber, yarn, or fabric surface, allowing the liquid component to get vaporized and the adhesive, if present, to get cured or solidified.

In the disclosed process, step (c) may contain immersing the graphene-coated fiber, yarn, or fabric in a metallizing bath. In a preferred procedure, step (c) includes a step of dipping the fiber, yarn, or fabric containing the layer of bonded graphene sheets/conductive filler into and then retreating from a chemical plating bath containing a metal salt dissolved in a liquid medium to effect metallization of the fiber, yarn, or fabric surface.

In certain embodiments, the graphene dispersion or graphene/conductive filler mixture dispersion further contains an adhesive resin having an adhesive-to-graphene weight ratio from 1/5000 to 1/10.

The graphene sheets may be further decorated with nanoscaled particles or coating of a catalytic metal, having a diameter or thickness from 0.5 nm to 100 nm, selected from cobalt, nickel, copper, iron, manganese, tin, zinc, lead, bismuth, silver, gold, palladium, platinum, an alloy thereof, or a combination thereof.

The liquid medium may contain permanganic acid, phosphoric acid, nitric acid, or a combination thereof that is dissolved in said liquid medium. In certain embodiments, the liquid medium contains an acid, an oxidizer, a metal salt, or a combination thereof dissolved therein.

Step (c) may contain immersing the fiber, yarn, or fabric in a metallizing bath to accomplish chemical plating or electroless plating. The high electrical conductivity of deposited graphene sheets and conductive filler enables plating of metal layer(s) on the graphene-coated fiber, yarn, or fabric surface. Alternatively, one may choose to use physical vapor deposition, sputtering, plasma deposition, etc. to accomplish the final metallization procedure.

The disclosure also provides a graphene dispersion comprising multiple graphene sheets and an optional conductive filler dispersed in a liquid medium wherein the multiple graphene sheets contain single-layer or few-layer graphene sheets selected from a pristine graphene material having essentially zero % of non-carbon elements, or a non-pristine graphene material having 0.001% to 25% by weight of non-carbon elements wherein said non-pristine graphene is selected from graphene oxide, reduced graphene oxide, graphene fluoride, graphene chloride, graphene bromide, graphene iodide, hydrogenated graphene, nitrogenated graphene, doped graphene, chemically functionalized graphene, or a combination thereof, and wherein the dispersion further contains one or multiple species selected from (i) an adhesive resin dissolved or dispersed in the liquid medium, wherein an adhesive-to-graphene weight ratio is from 1/5000 to 1/10; (ii) an etchant selected from an acid, an oxidizer, a metal salt, or a combination thereof; (iii) nanoscaled particles or coating of a catalytic metal, having a diameter or thickness from 0.5 nm to 100 nm, selected from cobalt, nickel, copper, iron, manganese, tin, zinc, lead, bismuth, silver, gold, palladium, platinum, an alloy thereof, or a combination thereof; or (iv) a combination thereof. Preferably, the chemically functionalized graphene is attached to a graphene sheet to make the graphene exhibit a negative Zeta potential in a desired liquid medium.

The conductive filler may be selected from metal nanowires, carbon fibers, carbon nanofibers, carbon nanotubes, carbon-coated fibers, conductive polymer fibers, nanofibers or nanowires of SnO₂, ZnO₂, In₂O₃, or indium-tin oxide (ITO), a conductive polymer not in a fiber form, or a combination thereof. The metal nanowires may be selected from nanowires of silver (Ag), gold (Au), copper (Cu), platinum (Pt), zinc (Zn), cadmium (Cd), cobalt (Co), molybdenum (Mo), aluminum (Al), or a combination thereof. The conductive polymer is preferably selected from the group consisting of polydiacetylene, polyacetylene (PAc), polypyrrole (PPy), polyaniline (PAni), polythiophene (PTh), polyisothionaphthene (PITN), poly heteroarylenvinylene (PArV), in which the heteroarylene group can be the thiophene, furan or pyrrole, poly-p-phenylene (PpP), polyphthalocyanine (PPhc) and the like, and their derivatives, and combinations thereof.

In the graphene dispersion, nanoscaled particles or coating of a catalytic metal may be deposited or decorated on surfaces of said multiple graphene sheets. The acid may be selected from permanganic acid, phosphoric acid, nitric acid, chromic acid, chromosulfuric acid, carboxylic acid, acetic acid, and ascorbic acid, or a combination thereof.

The preferred chemical functional groups are already discussed in the earlier part of this section. Preferably, these functional groups are attached to graphene sheets that make the graphene exhibit a negative Zeta potential, typically from −55 mV to −0.1 mV, in a desired dispersion medium.

The graphene sheets dispersed in the liquid medium of a presently disclosed graphene dispersion preferably contain a functional group attached to the graphene sheets to make the graphene sheets exhibit a negative Zeta potential from −55 mV to −0.1 mV in the liquid medium. In certain embodiments, the graphene sheets contain a carboxylic, acyl, aryl, aralkyl, halogen, alkyl, amino, halogen, or thiol group.

The graphene dispersion may further contain one or multiple species selected from (i) an adhesive resin dissolved or dispersed in said liquid medium, wherein an adhesive-to-graphene weight ratio is from 1/5000 to 1/10; (ii) an etchant selected from an acid, an oxidizer, a metal salt, or a combination thereof; (iii) nanoscaled particles or coating of a catalytic metal, having a diameter or thickness from 0.5 nm to 100 nm, selected from cobalt, nickel, copper, iron, manganese, tin, zinc, lead, bismuth, silver, gold, palladium, platinum, an alloy thereof, or a combination thereof, or (iv) a combination thereof.

### BRIEF DESCRIPTION OF THE DRAWINGS

FIG. 1 A flow chart showing the most commonly used process for producing oxidized graphene sheets that entails chemical oxidation/intercalation, rinsing, and high-temperature exfoliation procedures.

FIG. 2 Schematic of a graphene-mediated metallized fiber.

FIG. 3 Schematic of a system for graphene-mediated metallization of a continuous fiber, yarn, or fabric.

### DESCRIPTION OF THE PREFERRED EMBODIMENTS

The following includes definitions of various terms and phrases used throughout this specification.

The term “graphene sheets” means a material comprising one or more planar sheets of bonded carbon atoms that are densely packed in a hexagonal crystal lattice in which carbon atoms are bonded together through strong in-plane covalent bonds, and further containing an intact ring structure throughout a majority of the interior. Preferably at least 80% of the interior aromatic bonds are intact. In the c-axis (thickness) direction, these graphene planes may be weakly bonded together through van der Waals forces. Graphene sheets may contain non-carbon atoms at their edges or surface, for example OH and COOH functionalities. The term graphene sheets includes pristine graphene, graphene oxide, reduced graphene oxide, halogenated graphene including graphene fluoride and graphene chloride, nitrogenated graphene, hydrogenated graphene, doped graphene, functionalized graphene, and combinations thereof. Typically, non-carbon elements comprise 0 to 25 weight % of graphene sheets. Graphene oxide may comprise up to 53% oxygen by weight. The term “doped graphene” encompasses graphene having less than 10% of a non-carbon element. This non-carbon element can include hydrogen, oxygen, nitrogen, magnesium, iron, sulfur, fluorine, bromine, iodine, boron, phosphorus, sodium, and combinations thereof. Graphene sheets may comprise single-layer graphene or few-layer graphene, wherein the few-layer graphene is defined as a graphene platelet formed of less than 10 graphene planes. Graphene sheets may also comprise graphene nanoribbons. “Pristine graphene” encompasses graphene sheets having essentially zero % of non-carbon elements. “Nanographene platelet” (NGP) refers to a graphene sheet having a thickness from less than 0.34 nm (single layer) to 100 nm (multi-layer).

The term “fabric” is defined as a non-woven web or felt, a woven material, a knit material, a braid, a netting, a macramé, a lace or a combination thereof.

The term “substantially” and its variations are defined as being largely but not necessarily wholly what is specified as understood by one of ordinary skill in the art, and in one non-limiting embodiment substantially refers to ranges within 10%, within 5%, within 1%, or within 0.5% of a referenced range.

The term “essentially” and its variations are defined as being largely but not necessarily wholly what is specified as understood by one of ordinary skill in the art, and in one non-limiting embodiment substantially refers to ranges within 10%, within 5%, within 1%, or within 0.5% of a referenced range.

Other objects, features and advantages of the present disclosure may become apparent from the following figures, description, and examples. It should be understood, however, that the figures, description, and examples, while indicating specific embodiments of the disclosure, are given by way of illustration only and are not meant to be limiting. In further embodiments, features from specific embodiments may be combined with features from other embodiments.

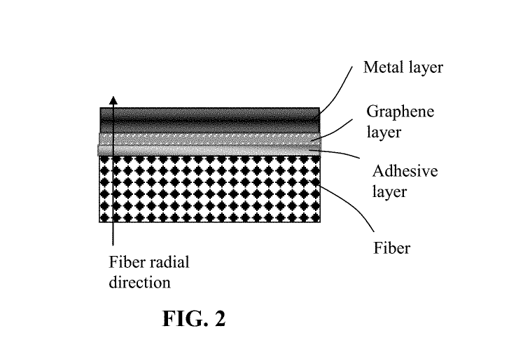

The present disclosure provides a surface-metalized fiber, yam, or fabric comprising: (a) a fiber, yarn, or fabric having a surface; (b) a graphene layer having a thickness from 0.34 nm to 20 μm and comprising multiple graphene sheets and an optional conducive filler coated on or bonded to the surface, with or without using an adhesive resin, to form a graphene-coated fiber, yarn, or fabric; and (c) a metal layer comprising a plated metal deposited on the graphene-coated fiber, yarn, or fabric; wherein the graphene sheets contain single-layer or few-layer graphene sheets selected from a pristine graphene, graphene oxide, reduced graphene oxide, graphene fluoride, graphene chloride, graphene bromide, graphene iodide, hydrogenated graphene, nitrogenated graphene, doped graphene, chemically functionalized graphene, or a combination thereof. A metallized fiber is schematically illustrated in FIG. 2.

The multiple graphene sheets and the conductive filler (if present) are bonded to the fiber, yarn, or fabric surface with or without an adhesive resin. The first layer (the graphene layer) has a thickness typically from 0.34 nm to 20 μm (preferably from 1 nm to 1 μm and further preferably from 1 nm to 100 nm). The second layer (covering metal layer) preferably has a thickness from 0.5 nm to 1.0 mm, more preferably from 1 nm to 10 μm, and most preferably from 10 nm to 1 μm. This metal-plated fiber, yarn, or fabric can be easily and readily produced using surprisingly simple and effective methods that are also herein described. Functionalized graphene sheets are surprisingly capable of bonding to many types of fiber, yarn, or fabric surfaces without using an adhesive resin.

In certain embodiments, the surface-metalized fiber, yarn, or fabric is used in a wide variety of components; e.g. a vehicle component, an electrical appliance, an electronic device, a food packaging bag, a protective clothing, an antistatic fabric or bag, a susceptor in microwave cooking, a blanket, an anti-reflection fabric, a children's toy, or a solar control window fabric. The electric appliance or electronic device may contain a wi-fi device, a cell phone, a coffee machine, a LED lamp housing, a wearable device, an electronic watch, a laptop computer, a tablet computer, or an EMI shielding layer for electronic equipment.

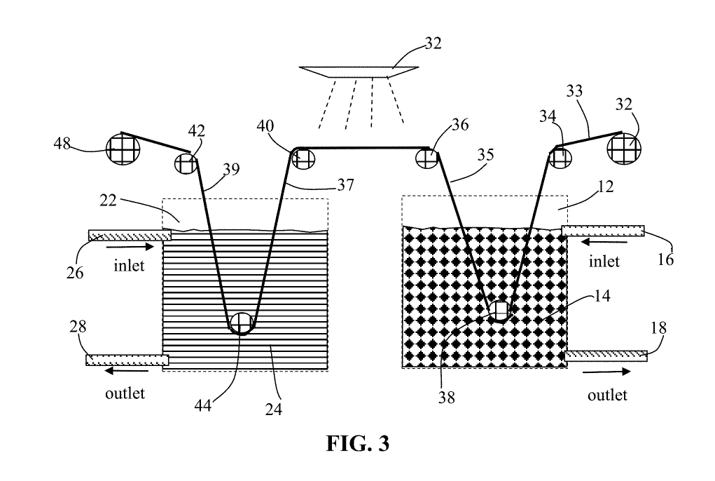

The present disclosure also provides an apparatus that can be used to produce the surface-metallized fiber, yarn, or fabric. In certain embodiments, as illustrated in FIG. 3, the apparatus may comprise a fiber/yam/fabric feeder roller 32 that feeds a fiber, yarn, or fabric 33 into a graphene deposition chamber (e.g. a graphene dispersion bath 12) that accommodates a graphene dispersion 14 comprising multiple graphene sheets and an optional conducive filler dispersed in a first liquid medium and an optional adhesive resin dissolved in the first liquid medium. One primary surface of a fabric may be covered with a plastic layer or paper if this surface is not to be metallized. Guiding rollers or rods (e.g. 34, 38, 36) are used to guide the movement of the fiber, yarn, or fabric 33. The fiber, yarn, or fabric is moved to immerse into the graphene dispersion 14 contained in the graphene deposition chamber 12. The graphene deposition chamber 12 is operated to deposit the graphene sheets and optional conductive filler to a fiber, yarn, or fabric surface for forming a graphene-coated fiber, yam, or fabric (e.g. 35). The graphene-coated, graphene-deposited or graphene-covered fiber, yam, or fabric is then moved to enter a heating/drying/curing zone (e.g. underneath a heating/drying/curing device 32), allowing the graphene sheets and the optional conductive filler to get coated on or bonded to the fiber, yarn, or fabric surface, thereby forming a graphene-coated fiber, yam, or fabric 37.

With the assistance of the guiding rollers/rods 40, 44, 42, the graphene-coated fiber, yam, or fabric 37 is guided to move into a metallization chamber (e.g. a metal plating bath 22), disposed nearby the graphene dispersion bath 12, which accommodates a plating solution 24 for plating a layer of a desired metal on the surface of a graphene-coated fiber, yarn, or fabric to obtain the surface-metalized fiber, yarn, or fabric 39. The metallized fiber, yarn, or fabric is then wound on a winding roller 48 (take-up roller). It may be noted that both primary surfaces of a fabric would be metallized if both surfaces of the fabric are not covered by a sheet of paper or plastic. Only one primary surface is metallized if the other primary surface is covered, preventing the graphene solution from contacting this surface.

Preferably, the graphene deposition chamber 12 has an inlet 16 through which fresh graphene dispersion may be pumped into the graphene deposition chamber and an outlet 18 through which spent graphene dispersion may be pumped out, respectively. Further preferably, the metallization chamber 22 has an inlet 26 through which fresh plating solution may be pumped into the metallization chamber and an outlet 28 through which spent plating solution may be pumped out, respectively.

The apparatus may further comprise a drying, heating, or curing provision 32 in a working relation with the graphene deposition chamber (e.g. above and between the graphene dispersion bath and the metallization chamber) for partially or completely removing the first liquid medium from the graphene-coated fiber, yam, or fabric and/or for polymerizing or curing the optional adhesive resin for producing the at least a graphene-coated fiber, yarn, or fabric containing multiple graphene sheets that are bonded to a fiber, yarn, or fabric surface.

In the apparatus, the plating solution 24 may contain a chemical plating solution, an electrochemical plating solution, or an electrophoretic solution. Preferably, the plating solution contains a chemical plating solution comprising a metal salt dissolved in water or an organic solvent (e.g. CuSO₄ or NiNO₃ dissolved in water for Cu plating or Ni plating). The various graphene sheets bonded on a polymer component surface are surprisingly capable of attracting metal ions to the graphene-covered or graphene-coated fiber, yarn, or fabric surface. The adhesion of metal on this surface is surprisingly strong, scratch-resistant, and hard. The deposited metal layer provides the desired gloss and metal appearance on the fiber, yam, or fabric surface.

The operation of the aforementioned procedures may be conducted in a continuous or intermittent manner and can be fully automated.

In certain embodiments, the conductive filler is selected from metal nanowires, carbon fibers, carbon nanofibers, carbon nanotubes, carbon-coated fibers, conductive polymer fibers, nanofibers or nanowires of SnO₂, ZnO₂, In₂O₃, or indium-tin oxide (ITO), a conductive polymer not in a fiber form, or a combination thereof. The metal nanowires are preferably selected from nanowires of silver (Ag), gold (Au), copper (Cu), platinum (Pt), zinc (Zn), cadmium (Cd), cobalt (Co), molybdenum (Mo), aluminum (Al), or a combination thereof. The conductive polymer is preferably selected from the group consisting of polydiacetylene, polyacetylene (PAc), polypyrrole (PPy), polyaniline (PAni), polythiophene (PTh), polyisothionaphthene (PITN), polyheteroarylenvinylene (PArV), in which the heteroarylene group can be the thiophene, furan or pyrrole, poly-p-phenylene (PpP), polyphthalocyanine (PPhc) and the like, and their derivatives, and combinations thereof.

The chemically functionalized graphene sheets are preferably those exhibiting a negative Zeta potential in a given dispersion, typically in the range from −55 mV to −0.1 mV. These functionalized graphene sheets typically have a functional group that is attached to these sheets for imparting negative Zeta potential thereto. Zeta potential is the potential difference between the dispersion medium and the stationary layer of fluid attached to the dispersed particles (e.g. graphene sheets) dispersed in this dispersion medium (e.g. water, organic solvent, electrolyte etc.). Several commercially available instruments (e.g. Zetasizer Nano from Malvern Panalytical and SZ-100 from Horiba Scientific) can be used to measure the Zeta potential of different types of graphene sheets in different dispersion mediums.

It may be noted that a given type of graphene (e.g. graphene oxide or reduced graphene oxide) can exhibit a positive or negative Zeta potential and its value can vary, depending upon the chemical functional groups attached to graphene sheets and the dispersion medium used. Unless otherwise specified, the Zeta potential values provided are for the graphene sheets dispersed in an aqueous solution having a pH vale of 5.0-9.0 (mostly 7.0).

In some embodiments, the chemically functionalized graphene sheets contain a chemical functional group selected from alkyl or aryl silane, alkyl or aralkyl group, hydroxyl group, carboxyl group, amine group, sulfonate group (—SO₃H), aldehydic group, quinoidal, fluorocarbon, or a combination thereof. Alternatively, the functional group contains a derivative of an azide compound selected from the group consisting of 2-azidoethanol, 3-azidopropan-1-amine, 4-(2-azidoethoxy)-4-oxobutanoic acid, 2-azidoethyl-2-bromo-2-methylpropanoate, chlorocarbonate, azidocarbonate, dichlorocarbene, carbene, aryne, nitrene, (R−)-oxycarbonyl nitrenes, where R=any one of the following groups,

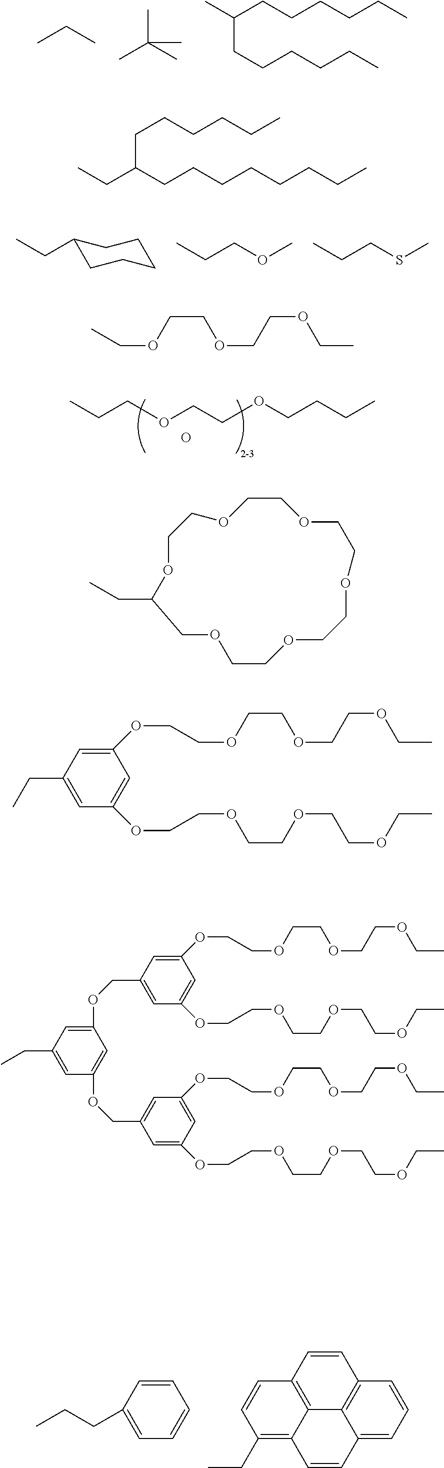

and combinations thereof.

In certain embodiments, the functional group is selected from the group consisting of hydroxyl, peroxide, ether, keto, and aldehyde. In certain embodiments, the functionalizing agent contains a functional group selected from the group consisting of SO₃H, COOH, NH₂, OH, R′CHOH, CHO, CN, COCl, halide, COSH, SH, COOR′, SR′, SiR′₃, Si(—OR′—)_{y}R′₃-y, Si(—O—SiR′₂—)OR′, R″, Li, AlR′₂, Hg—X, TlZ₂ and Mg—X; wherein y is an integer equal to or less than 3, R′ is hydrogen, alkyl, aryl, cycloalkyl, or aralkyl, cycloaryl, or poly(alkylether), R″ is fluoroalkyl, fluoroaryl, fluorocycloalkyl, fluoroaralkyl or cycloaryl, X is halide, and Z is carboxylate or trifluoroacetate, and combinations thereof.

The functional group may be selected from the group consisting of amidoamines, polyamides, aliphatic amines, modified aliphatic amines, cycloaliphatic amines, aromatic amines, anhydrides, ketimines, diethylenetriamine (DETA), triethylene-tetramine (TETA), tetraethylene-pentamine (TEPA), polyethylene polyamine, polyamine epoxy adduct, phenolic hardener, non-brominated curing agent, non-amine curatives, and combinations thereof.

In some embodiments, the functional group may be selected from OY, NHY, O═C—OY, P═C—NR′Y, O═C—SY, O═C—Y, —CR′1-OY, N′Y or C′Y, and Y is a functional group of a protein, a peptide, an amino acid, an enzyme, an antibody, a nucleotide, an oligonucleotide, an antigen, or an enzyme substrate, enzyme inhibitor or the transition state analog of an enzyme substrate or is selected from R′—OH, R′—NR′₂, R′SH, R′CHO, R′CN, R′X, R′N⁺(R′)₃X⁻, R′SiR′₃, R′Si(—OR′—)_{y}R′_{3-y}, R′Si(—O—SiR′₂—)OR′, R′—R″, R′—N—CO, (C₂H₄O—)_{w}H, (—C₃H₆O—)_{w}H, (—C₂H₄O)_{w}—R′, (C₃H₆O)_{w}—R′, R′, and w is an integer greater than one and less than 200.

The present disclosure also provides a process for metallizing a fiber, yarn, or fabric surface (e.g. surface of an electrically non-conductive plastic fiber). The coating of fiber, yarn, or fabric surfaces with metals, also called galvanizing or polymer metallization, is becoming increasingly important. By polymer galvanizing methods, laminates which combine advantages of polymers and metals are produced. The use of polymer components (e.g. a fiber, yarn or fabric) can achieve a distinct reduction in weight in comparison to metal parts. Galvanization of fabrics may be conducted for decorative purposes, for EMI shielding, or for surface property modifications.

This section begins with the description of the most commonly used prior art process for producing metallized plastic articles. The problems associated with this prior art process are then highlighted. This is followed by a discussion of the presently disclosed process and the resulting products that overcome all these problems.

In a prior art process for metallization of fabrics, the fabrics are usually secured in frames and contacted with a plurality of different treatment fluids in a particular process sequence. As a first step, the fabrics are typically pretreated to remove impurities, such as greases, from the surface. Subsequently, etching treatments are used to roughen the surface to ensure adequate adhesion of the subsequent metal layers to the fabric surface. In the etching operation, the formation of a homogeneous structure in the form of recesses (e.g. surface openings or micro-caverns) on the fabric surface is particularly crucial. Subsequently, the roughened surface is treated with activators to form a catalytic surface for a subsequent chemical metallization or electroless plating. For this purpose, either the ionogenic activators or colloidal systems are used.

In a prior art procedure, plastic surfaces for activation with ionogenic systems are first treated with tin(II) ions, giving rise to firmly adhering gels of tin oxide hydrate after the treatment and rinsing with water. In the subsequent treatment with a palladium salt solution, palladium nuclei are formed on the surface through redox reaction with the tin(II) species. These palladium nuclei are catalytic for the chemical metallization. For activation with colloidal systems, generally colloidal palladium solutions are used, formed by reaction of palladium chloride with tin(II) chloride in the presence of excess hydrochloric acid.

After the activation, the parts are typically first chemically metallized using a metastable solution of a metallization bath. These baths generally comprise the metal to be deposited in the form of salts in an aqueous solution and a reducing agent for the metal salt. When the chemical metallization baths come into contact with the metal nuclei on the plastic surface (e.g. the palladium seeds), metal is formed by reduction, which is deposited on the surface as a firmly adhering layer. The chemical metallization step is commonly used to deposit copper, nickel or a nickel alloy with phosphorus and/or boron.

The chemically metallized polymer surface may then be electrolytically deposited further with metal layers. Typically, an electrolytic deposition of copper layers or further nickel layers is conducted before the desired decorative chromium layer is applied electrochemically.

There are several major issues associated with this prior art process for producing metallized articles:
1) The process is tedious, involving many steps: pretreatment, chemical etching, activation, chemical metallization, and electrolytic deposition of multiple metal layers (hence, multiple steps).
2) The most commonly used etchant is the chromium-sulfuric acid or chromosulfuric acid (chromium trioxide in sulfuric acid), especially for ABS (acrylonitrile-butadiene-styrene copolymer) or polycarbonate. Chromium-sulfuric acid is very toxic and requires special precautions in the etching procedure, after treatment, and disposal. Because of chemical processes in the etching treatment (e.g. the reduction of the chromium compound used), the chromium-sulfuric acid etchant is used up and is generally not reusable.
3) A critical process step in plastic galvanizing is the creation of micro-caverns to enable the adhesion of the metal on the plastic surface. These micro-caverns serve, in the later metallization steps, as the starting point for the growth of the metal nuclei. These micro-caverns, in general, have a size on the order of 0.1 to 10 μm. Especially, these micro-caverns show a depth (i e. an extent from the plastic surface toward the interior) in the range from 0.1 to 10 μm. Unfortunately, surface micro-caverns can be stress concentration sites that weaken the strength of the plastic component.
4) After the etching or roughening of the surface, the surface first is activated with colloidal palladium or ionogene palladium. This activation, in the case of the colloidal process, is followed by a removal of a protective tin colloid or, in the case of the ionogene process, a reduction to the elemental palladium. Subsequently, copper or nickel is chemically deposited on the plastic surface as a conducting layer. Following this, galvanizing or metallizing takes place. In practice, this direct metallizing of the plastic surface works only for certain plastics. If sufficient roughening of the plastic, or the formation of suitable micro-caverns, is not possible by etching the plastic surface, a functionally secure adherence of the metal layer to the plastic surface is not guaranteed. Therefore, in the prior art process, the number of plastics capable of being coated is greatly limited.
5) Nobel metals, such as palladium, are very expensive.

The present disclosure provides a graphene-mediated process for producing metallized fiber, yarn, or fabric. The disclosed method overcomes all of these problems.

In certain embodiments, the process comprises: (a) optionally treating a surface of a fiber, yarn, or fabric to prepare a surface-treated fiber, yarn, or fabric (this procedure being optional since the graphene dispersion per se is capable of pre-treating the polymer surface); (b) providing a graphene dispersion (also herein referred to as graphene/conductive filler mixture dispersion) comprising multiple graphene sheets (functionalized or un-functionalized) and an optional conductive filler (in the form of nanofibers, nanoparticles, nanowires, etc.) dispersed in a liquid medium (along with an optional adhesive resin dissolved in the liquid medium), bringing the surface-treated or un-treated fiber, yarn, or fabric into contact with the graphene dispersion, and enabling deposition of the graphene sheets and the conductive filler onto a surface of the fiber, yarn, or fabric wherein the graphene sheets and the conductive filler are bonded to the surface to form a layer of bonded graphene sheets/conductive filler that covers (partially or fully) a fiber, yarn, or fabric surface; and (c) chemically, physically, electrochemically or electrolytically depositing a layer of a metal onto a surface of the covered fiber, yarn, or fabric surface to form the surface-metalized fiber, yam, or fabric. Again, step (a) is optional in the disclosed method.

The fiber can be a polymer fiber, a glass fiber, a ceramic fiber, or a carbon fiber, etc.

As examples, the fiber may be selected from a filament form of polyethylene, polypropylene, polybutylene, polyvinyl chloride, polycarbonate, acrylonitrile-butadiene-styrene (ABS), polyester, polyvinyl alcohol, poly vinylidiene fluoride (PVDF), polytetrafluoroethylene (PTFE), polyphenylene oxide (PPO), poly methyl methacrylate (PMMA), a copolymer thereof, a polymer blend thereof, or a combination thereof. The polymer may also be selected from phenolic resin, poly furfuryl alcohol, polyacrylonitrile, polyimide, polyamide, polyoxadiazole, polybenzoxazole, polybenzobisoxazole, polythiazole, polybenzothiazole, polybenzobisthiazole, poly(p-phenylene vinylene), polybenzimidazole, polybenzobisimidazole, a copolymer thereof, a polymer blend thereof, or a combination thereof.

In certain embodiments, step (a) of the disclosed process is omitted from the process since the liquid medium in the graphene dispersion is generally capable of removing grease and other undesirable species from fiber, yarn, or fabric surfaces. Some liquid mediums in graphene dispersions can further provide etching effects to create small surface recesses having a depth <0.1 μm (a mild etching condition). In these situations, the entire process requires only three simple steps.

In certain embodiments, step (a) can include a step of subjecting the fiber, yarn, or fabric surface to a grinding treatment, an etching treatment, or a combination thereof. In some embodiments, step (a) includes a step of subjecting the fiber, yarn, or fabric surface to an etching treatment using an etchant selected from an acid, an oxidizer, a metal salt, or a combination thereof. Preferably, step (a) includes a step of subjecting the fiber, yarn, or fabric surface to an etching treatment without using chromic acid or chromosulfuric acid. More preferably, step (a) includes a step of subjecting the fiber, yam, or fabric surface to an etching treatment using an etchant selected from an acid, an oxidizer, a metal salt, or a combination thereof under a mild etching condition wherein etching is conducted at a sufficiently low temperature for a sufficiently short period of time so as not to create micro-caverns having an average size greater than 0.1 μm.

The mild etching referred to in the disclosure means that the “etching”, or the treatment of the plastic surface with a etching solution occurs at low temperatures and/or within a shorter time period at a low concentration of the etching solution. Mild etching conditions can be realized when one of the preceding three conditions is met. The low temperature referred to in the disclosure means a maximum temperature of 40° C., preferably <30° C., and most preferably from 15° C. to 25° C. With the low temperatures mentioned above, the pre-treatment with the etching solution takes place over a time period of 3 to 15 minutes, preferably 5 to 15 minutes and even more preferably 5 to 10 minutes. The treatment period is the shorter the higher the temperature. However, mild etching conditions can be also achieved at temperatures in excess of 40° C. if the treatment period selected is appropriately short. According to one embodiment of the disclosure, the etching treatment takes place at temperatures of 40° C. to 95° C., preferably 50° C. to 70° C., for a treatment period of 15 seconds to 5 minutes, preferably 0.5 to 3 minutes. In practical terms, the process temperature and/or process time is selected in accordance with the type of the etching solution employed.

Mild etching also means that, contrary to the prior art processes referred to above, roughening of the fiber, yarn, or fabric surface, or the creation of micro-caverns in the fiber, yarn, or fabric surface does not occur. The micro-caverns created with etching according to the prior art process normally have a diameter or depth in the size range of 0.1 to 10 μm. In the instant disclosure, the etching conditions may be adjusted so that small openings or pores having a diameter or depth of <100 nm are created in the fiber, yarn, or fabric surface. Preferably, opening of <50 nm are created. In this connection, depth means the extent of the openings/gateways from the polymer surface into the polymer interior. In the presently disclosed process wherein step (a) is eliminated, the liquid medium in the graphene dispersion normally can create openings or pores having a size <0.1 μm. Contrary to what the prior art teachings suggest, we have surprisingly observed that the presently disclosed graphene-mediated metallization approach does not require the creation of micro-caverns greater than 0.1 μm in size. The approach works even on highly smooth surface.

In step (a), the etching treatment can be realized with an etching solution, by a plasma treatment, by plasma etching, by ion bombardment, or by combinations thereof.

Preferably, an etching solution used for etching contains at least one oxidizer. Mild etching within the scope of the disclosure also means that an oxidizer is used in a low concentration. Permanganate and/or peroxodisulfate and/or periodate and/or peroxide can be used as oxidizers. In accordance with one embodiment of the disclosure, etching is by an acid etching solution which contains at least one oxidizer. Instead of using a separate etching solution, the oxidizer and/or the acid or basic solution (discussed below) may be added into the graphene dispersion and, as such, step (a) and step (b) are essentially combined into one single step.

Preferably, an aqueous etching solution is used which contains permanganate and phosphoric acid (H₃PO₄) and/or sulfuric acid. Potassium permanganate may be used as the permanganate. Very much preferred is the use of an acid etching solution which only contains phosphoric acid or principally phosphoric acid and only a small amount of sulfuric acid.

According to another embodiment of the disclosure, etching treatment is by a basic aqueous solution, containing permanganate. Here again, potassium permanganate is preferably used. The basic aqueous solution may contain lye. The type of etching solution used depends on the type of polymer to be treated. The preferred concentration of the oxidizer in the etching solution is 0.05 to 0.6 mol/l. Preferably, the etching solution contains 0.05 to 0.6 mol/l permanganate or persulfate. The etching solution may contain 0.1 to 0.5 mol/l periodate or hydrogen peroxide. The preferred permanganate proportion is 1 g/l up to the solubility limit of the permanganate, preferably potassium permanganate. The permanganate solution preferably contains 2 to 15 g/l permanganate, more preferably 2 to 15 g/l potassium permanganate. The permanganate solution may contain a wetting agent.

Mild etching can also be achieved by the use of a dilute aqueous persulfate solution or periodite solution or a dilute aqueous peroxide solution (used as a separate etching solution or as part of the graphene dispersion). Preferably, the mild etching treatment with an etching solution is carried out while agitating the solution. After the mild etching, the plastic surface is rinsed, for example, for 1 to 3 minutes in water. In accordance with a preferred embodiment of the disclosure, the treatment with the metal salt solution is conducted at a temperature <30° C., preferably between 15 and 25° C. (including room temperature). In practice, the treatment with the metal salt solution is performed without agitation. The preferred treatment time is 30 seconds to 15 minutes, preferably 3 to 12 minutes. Preferably, a metal salt solution is used which has a pH value of between 7.5 and 12.5, preferably adjusted to between 8 and 12. Preferably, a metal salt solution is used which contains ammonia and/or at least one amine. The above-mentioned pH value adjustment can be effected with the help of ammonia, and an alkaline metal salt solution is preferably used. One may also use a metal salt solution which contains one or more amines. For example, the metal salt solution may contain monoethanolamine and/or triethanolamine. Treatment with the metal salt solution means preferably the immersion of the polymer component surface into the metal salt solution.

In certain embodiments, step (b) includes immersing or dipping the surface-treated or un-treated fiber, yarn, or fabric in the graphene dispersion and then removing the fiber, yarn, or fabric from the graphene dispersion to effect deposition of graphene sheets and the conductive filler onto a surface of the surface-treated fiber, yarn, or fabric wherein the graphene sheets and the conductive fillers are bonded to the surface to form a layer of bonded graphene sheets/conductive filler. Alternatively, one may simply spray graphene dispersion over the fiber, yarn, or fabric surface, allowing the liquid component to get vaporized and the adhesive, if present, to get cured or solidified.

The adhesive resin layer, if present, may be formed of an adhesive resin composition including an adhesive resin as a main ingredient. The adhesive resin composition may include a curing agent and a coupling agent along with the adhesive resin. Examples of the adhesive resin may include an ester resin, a urethane resin, a urethane ester resin, an acrylic resin, and an acrylic urethane resin, specifically ester resins including neopentyl glycol (NPG), ethylene glycol (EG), isophthalic acid, and terephthalic acid. The curing agent may be present in an amount of 1 to 30 parts by weight based on 100 parts by weight of the adhesive resin. The coupling agent may include epoxy silane compounds.

Curing of this adhesive layer may be conducted via heat, UV, or ionizing radiation. This can involve heating the layers coated with the heat-curable composition to a temperature of at least 70° C., preferably of 90° C. to 150° C., for at least 1 minute (typically up to 2 hours and more typically from 2 minutes to 30 minutes), so as to form a hard coating layer.

The fiber, yarn, or fabric surfaces may be brought to be in contact with the graphene dispersion using dipping, coating (e.g. doctor-blade coating, bar coating, slot-die coating, comma coating, reversed-roll coating, etc.), roll-to-roll process, inkjet printing, screen printing, micro-contact, gravure coating, spray coating, ultrasonic spray coating, electrostatic spray coating, and flexographic printing. The thickness of the hard coat or adhesive layer is generally about 1 nm to 10 μm, preferably 10 nm to 2 μm.

For thermally curable resins, the polyfunctional epoxy monomer may be selected preferably from diglycerol tetraglycidyl ether, dipentaerythritol tetraglycidyl ether, sorbitol polyglycidyl ether, polyglycerol polyglycidyl ether, pentaerythritol polyglycidyl ether (e.g. pentaerythritol tetraglycidyl ether), or a combination thereof. The bi- or tri-functional epoxy monomer can be selected from the group consisting of trimethylolethane triglycidyl ether, trimethylolmethane triglycidyl ether, trimethylolpropane triglycidyl ether, triphenylolmethane triglycidyl ether, trisphenol triglycidyl ether, tetraphenylol ethane triglycidyl ether, tetraglycidyl ether of tetraphenylol ethane, p-aminophenol triglycidyl ether, 1,2,6-hexanetriol triglycidyl ether, glycerol triglycidyl ether, diglycerol triglycidyl ether, glycerol ethoxylate triglycidyl ether, castor oil triglycidyl ether, propoxylated glycerine triglycidyl ether, ethylene glycol diglycidyl ether, 1,4-butanediol diglycidyl ether, neopentyl glycol diglycidyl ether, cyclohexanedimethanol diglycidyl ether, dipropylene glycol diglycidyl ether, polypropylene glycol diglycidyl ether, dibromoneopentyl glycol diglycidyl ether, hydrogenated bisphenol A diglycidyl ether, (3,4-epoxycyclohexane) methyl 3,4-epoxycylohexylcarboxylate and mixtures.

In certain embodiments, the heat-curable compositions of the present invention advantageously further contain small amounts, preferably from 0.05 to 0.20% by weight, of at least one surface active compound. The surface active agent is important for good wetting of the substrate resulting in satisfactory final hard-coating.

The UV radiation curable resins and lacquers usable for the adhesive layer useful in this disclosure are those derived from photo polymerizable monomers and oligomers, such as acrylate and methacrylate oligomers (the term “(meth)acrylate” used herein refers to acrylate and methacrylate), of polyfunctional compounds, such as polyhydric alcohols and their derivatives having (meth)acrylate functional groups such as ethoxylated trimethylolpropane tri(meth)acrylate, tripropylene glycol di(meth)acrylate, trimethylolpropane tri(meth)acrylate, diethylene glycol di(meth)acrylate, pentaerythritol tetra(meth)acrylate, pentaerythritol tri(meth)acrylate, dipentaerythritol hexa(meth)acrylate, 1,6-hexanediol di(meth)acrylate, or neopentyl glycol di(meth)acrylate and mixtures thereof, and acrylate and methacrylate oligomers derived from low-molecular weight polyester resin, polyether resin, epoxy resin, polyurethane resin, alkyd resin, spiroacetal resin, epoxy acrylates, polybutadiene resin, and polythiol-polyene resin.

The UV polymerizable monomers and oligomers are coated (e.g. after retreating from dipping) and dried, and subsequently exposed to UV radiation to form an optically clear cross-linked abrasion resistant layer. The preferred UV cure dosage is between 50 and 1000 mJ/cm².

UV-curable resins are typically ionizing radiation-curable as well. The ionizing radiation-curable resins may contain a relatively large amount of a reactive diluent. Reactive diluents usable herein include monofunctional monomers, such as ethyl (meth)acrylate, ethylhexyl (meth)acrylate, styrene, vinyltoluene, and N-vinylpyrrolidone, and polyfunctional monomers, for example, trimethylolpropane tri(meth)acrylate, hexanediol (meth)acrylate, tripropylene glycol di(meth)acrylate, diethylene glycol di(meth)acrylate, pentaerythritol tri(meth)acrylate, dipentaerythritol hexa(meth)acrylate, 1,6-hexanediol di(meth)acrylate, or neopentyl glycol di(meth)acrylate.

In the disclosed method, step (c) may contain immersing the graphene-bonded fiber, yarn, or fabric in a metallizing bath. The high electrical conductivity of deposited graphene sheets readily enables electro-plating of metal layer(s) on graphene/conductive filler-coated fiber, yarn, or fabric surfaces.

Alternatively and advantageously, the final metallization step may be accomplished by using a chemical plating method without using an expensive noble metal solution. This step can include dipping (immersing) a graphene/conductive filler-coated fiber, yarn, or fabric in a chemical plating bath which contains a metal salt (salt of an intended metal, such as Cu, Ni, or Co) dissolved in a liquid medium (e.g. CuSO₄ in water or NiNO₃ in water). Such a dipping procedure typically requires a contact time from 3 seconds to 30 minutes.

A copper metal plating bath (or Ni plating bath) may comprise a copper salt (or Ni salt) and an additive consumption-inhibiting compound. The additive consumption-inhibiting compound may comprise methyl sulfoxide, methyl sulfone, tetramethylene sulfoxide, thioglycolic acid, 2 (5H) thiophenone, 1,4-dithiane, trans-1,2-dithiane, tetrahydrothiophene-3-one, 3-thiophenemethanol, 1,3,5-trithiane, 3-thiopheneacetic acid, thiotetronic acid, crown thioethers, tetrapyrids, dipropyltrisulfide, bis(3-triethoxy silyl propyltetrasulfide, dimethyl tetrasulfide, methyl methanethiosulfate, (2-sulfonatoethyl) methane, p-tolyldisulfoxide, p-tolyldisulfone, bis(phenylsulfonyl)sulfide, 4-(chlorosulfonyl) benzoic acid, isopropyl sulfonyl chloride, 1-propane sulfonyl chloride, thioctic acid, 4-hydroxy-benzene sulfonic acid, phenyl vinyl sulfone, or mixtures thereof.

In certain highly preferred embodiments, the aforementioned operations may be conducted in a roll-to-roll or reel-to-reel manner, as illustrated in FIG. 3. In some preferred embodiments, the process comprises: (a) Feeding a continuous fiber, yarn, or fabric from a feeder roller or spool into a graphene deposition chamber, wherein the graphene deposition chamber contains therein a graphene dispersion comprising multiple graphene sheets and an optional conducive filler dispersed in a first liquid medium and an optional adhesive resin dissolved in this first liquid medium; (b) Operating the graphene deposition chamber to deposit the graphene sheets and optional conductive filler to a surface of the fiber, yarn, or fabric for forming a graphene-coated fiber, yarn, or fabric; (c) Moving the graphene-coated fiber, yam, or fabric into a metallization chamber which accommodates a plating solution therein for plating a layer of a desired metal onto the graphene-coated fiber, yarn, or fabric to obtain a surface-metalized fiber, yarn, or fabric; and (d) Operating a winding roller to collect the surface-metalized fiber, yarn, or fabric.

Alternatively, one may choose to use physical vapor deposition, sputtering, plasma deposition, etc. to accomplish the final metallization procedure.

The preparation of graphene sheets and graphene dispersions is described as follows: Carbon is known to have five unique crystalline structures, including diamond, fullerene (0-D nanographitic material), carbon nanotube or carbon nanofiber (1-D nanographitic material), graphene (2-D nanographitic material), and graphite (3-D graphitic material). The carbon nanotube (CNT) refers to a tubular structure grown with a single wall or multi-wall. Carbon nanotubes (CNTs) and carbon nanofibers (CNFs) have a diameter on the order of a few nanometers to a few hundred nanometers. Their longitudinal, hollow structures impart unique mechanical, electrical and chemical properties to the material. The CNT or CNF is a one-dimensional nanocarbon or 1-D nanographite material.

Our research group pioneered the development of graphene materials and related production processes as early as 2002: (1) B. Z. Jang and W. C. Huang, “Nano-scaled Graphene Plates,” U.S. Pat. No. 7,071,258 (Jul. 4, 2006), application submitted on Oct. 21, 2002; (2) B. Z. Jang, et al. “Process for Producing Nano-scaled Graphene Plates,” U.S. patent application Ser. No. 10/858,814 (Jun. 3, 2004) (U.S. Patent Pub. No. 2005/0271574); and (3) B. Z. Jang, A. Zhamu, and J. Guo, “Process for Producing Nano-scaled Platelets and Nanocomposites,” U.S. patent application Ser. No. 11/509,424 (Aug. 25, 2006) (U.S. Pat. Pub. No. 2008-0048152).

A single-layer graphene sheet is composed of carbon atoms occupying a two-dimensional hexagonal lattice. Multi-layer graphene is a platelet composed of more than one graphene plane. Individual single-layer graphene sheets and multi-layer graphene platelets are herein collectively called nanographene platelets (NGPs) or graphene materials. NGPs include pristine graphene (essentially 99% of carbon atoms), slightly oxidized graphene (<5% by weight of oxygen), graphene oxide (≥5% by weight of oxygen), slightly fluorinated graphene (<5% by weight of fluorine), graphene fluoride ((≥5% by weight of fluorine), other halogenated graphene, and chemically functionalized graphene.

NGPs have been found to have a range of unusual physical, chemical, and mechanical properties. For instance, graphene was found to exhibit the highest intrinsic strength and highest thermal conductivity of all existing materials. Although practical electronic device applications for graphene (e.g., replacing Si as a backbone in a transistor) are not envisioned to occur within the next 5-10 years, its application as a nano filler in a composite material and an electrode material in energy storage devices is imminent. The availability of processable graphene sheets in large quantities is essential to the success in exploiting composite, energy, and other applications for graphene.

The processes for producing NGPs and NGP nanocomposites were recently reviewed by us [Bor Z. Jang and A Zhamu, “Processing of Nano Graphene Platelets (NGPs) and NGP Nanocomposites: A Review,” J. Materials Sci. 43 (2008) 5092-5101].

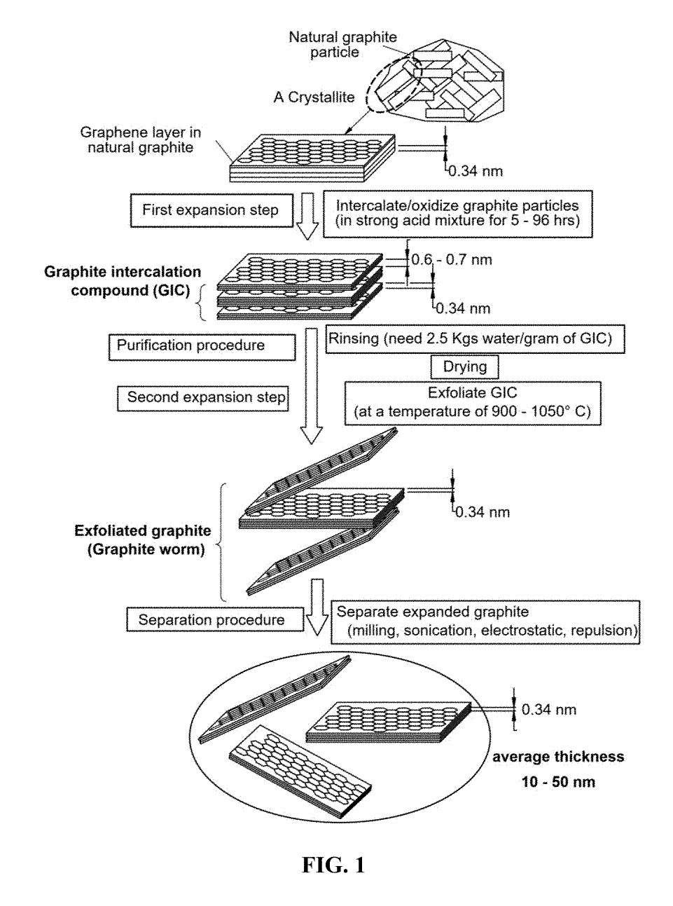

A highly useful approach (FIG. 1) entails treating natural graphite powder with an intercalant and an oxidant (e.g., concentrated sulfuric acid and nitric acid, respectively) to obtain a graphite intercalation compound (GIC) or, actually, graphite oxide (GO). [William S. Hummers, Jr., et al., Preparation of Graphitic Oxide, Journal of the American Chemical Society, 1958, p. 1339.] Prior to intercalation or oxidation, graphite has an inter-graphene plane spacing of approximately 0.335 nm (L_{d}=½ d₀₀₂=0.335 nm). With an intercalation and oxidation treatment, the inter-graphene spacing is increased to a value typically greater than 0.6 nm. This is the first expansion stage experienced by the graphite material during this chemical route. The obtained GIC or GO is then subjected to further expansion (often referred to as exfoliation) using either a thermal shock exposure or a solution-based, ultrasonication-assisted graphene layer exfoliation approach.

In the thermal shock exposure approach, the GIC or GO is exposed to a high temperature (typically 800-1,050° C.) for a short period of time (typically 15 to 60 seconds) to exfoliate or expand the GIC or GO for the formation of exfoliated or further expanded graphite, which is typically in the form of a “graphite worm” composed of graphite flakes that are still interconnected with one another. This thermal shock procedure can produce some separated graphite flakes or graphene sheets, but normally the majority of graphite flakes remain interconnected. Typically, the exfoliated graphite or graphite worm is then subjected to a flake separation treatment using air milling, mechanical shearing, or ultrasonication in water. Hence, approach 1 basically entails three distinct procedures: first expansion (oxidation or intercalation), further expansion (or “exfoliation”), and separation.

In the solution-based separation approach, the expanded or exfoliated GO powder is dispersed in water or aqueous alcohol solution, which is subjected to ultrasonication. It is important to note that in these processes, ultrasonification is used after intercalation and oxidation of graphite (i.e., after first expansion) and typically after thermal shock exposure of the resulting GIC or GO (after second expansion). Alternatively, the GO powder dispersed in water is subjected to an ion exchange or lengthy purification procedure in such a manner that the repulsive forces between ions residing in the inter-planar spaces overcome the inter-graphene van der Waals forces, resulting in graphene layer separations.

In the aforementioned examples, the starting material for the preparation of graphene sheets or NGPs is a graphitic material that may be selected from the group consisting of natural graphite, artificial graphite, graphite oxide, graphite fluoride, graphite fiber, carbon fiber, carbon nanofiber, carbon nanotube, mesophase carbon microbead (MCMB) or carbonaceous micro-sphere (CMS), soft carbon, hard carbon, and combinations thereof.

Graphite oxide may be prepared by dispersing or immersing a laminar graphite material (e.g., powder of natural flake graphite or synthetic graphite) in an oxidizing agent, typically a mixture of an intercalant (e.g., concentrated sulfuric acid) and an oxidant (e.g., nitric acid, hydrogen peroxide, sodium perchlorate, potassium permanganate) at a desired temperature (typically 0-70° C.) for a sufficient length of time (typically 4 hours to 5 days). The resulting graphite oxide particles are then rinsed with water several times to adjust the pH values to typically 2-5. The resulting suspension of graphite oxide particles dispersed in water is then subjected to ultrasonication to produce a dispersion of separate graphene oxide sheets dispersed in water. A small amount of reducing agent (e.g. Na₄B) may be added to obtain reduced graphene oxide (RDO) sheets.

In order to reduce the time required to produce a precursor solution or suspension, one may choose to oxidize the graphite to some extent for a shorter period of time (e.g., 30 minutes-4 hours) to obtain graphite intercalation compound (GIC). The GIC particles are then exposed to a thermal shock, preferably in a temperature range of 600-1,100° C. for typically 15 to 60 seconds to obtain exfoliated graphite or graphite worms, which are optionally (but preferably) subjected to mechanical shearing (e.g. using a mechanical shearing machine or an ultrasonicator) to break up the graphite flakes that constitute a graphite worm. Either the already separated graphene sheets (after mechanical shearing) or the un-broken graphite worms or individual graphite flakes are then re-dispersed in water, acid, or organic solvent and ultrasonicated to obtain a graphene dispersion.

The pristine graphene material is preferably produced by one of the following three processes: (A) Intercalating the graphitic material with a non-oxidizing agent, followed by a thermal or chemical exfoliation treatment in a non-oxidizing environment; (B) Subjecting the graphitic material to a supercritical fluid environment for inter-graphene layer penetration and exfoliation; or (C) Dispersing the graphitic material in a powder form to an aqueous solution containing a surfactant or dispersing agent to obtain a suspension and subjecting the suspension to direct ultrasonication to obtain a graphene dispersion.

In Procedure (A), a particularly preferred step comprises (i) intercalating the graphitic material with a non-oxidizing agent, selected from an alkali metal (e.g., potassium, sodium, lithium, or cesium), alkaline earth metal, or an alloy, mixture, or eutectic of an alkali or alkaline metal; and (ii) a chemical exfoliation treatment (e.g., by immersing potassium-intercalated graphite in ethanol solution).

In Procedure (B), a preferred step comprises immersing the graphitic material to a supercritical fluid, such as carbon dioxide (e.g., at temperature T>31° C. and pressure P>7.4 MPa) and water (e.g., at T>374° C. and P>22.1 MPa), for a period of time sufficient for inter-graphene layer penetration (tentative intercalation). This step is then followed by a sudden de-pressurization to exfoliate individual graphene layers. Other suitable supercritical fluids include methane, ethane, ethylene, hydrogen peroxide, ozone, water oxidation (water containing a high concentration of dissolved oxygen), or a mixture thereof.

In Procedure (C), a preferred step comprises (a) dispersing particles of a graphitic material in a liquid medium containing therein a surfactant or dispersing agent to obtain a suspension or slurry; and (b) exposing the suspension or slurry to ultrasonic waves (a process commonly referred to as ultrasonication) at an energy level for a sufficient length of time to produce a graphene dispersion of separated graphene sheets (non-oxidized NGPs) dispersed in a liquid medium (e.g. water, alcohol, or organic solvent).

NGPs can be produced with an oxygen content no greater than 25% by weight, preferably below 20% by weight, further preferably below 5%. Typically, the oxygen content is between 5% and 20% by weight. The oxygen content can be determined using chemical elemental analysis and/or X-ray photoelectron spectroscopy (XPS).

The laminar graphite materials used in the prior art processes for the production of the GIC, graphite oxide, and subsequently made exfoliated graphite, flexible graphite sheets, and graphene platelets were, in most cases, natural graphite. However, the present disclosure is not limited to natural graphite. The starting material may be selected from the group consisting of natural graphite, artificial graphite (e.g., highly oriented pyrolytic graphite, HOPG), graphite oxide, graphite fluoride, graphite fiber, carbon fiber, carbon nanofiber, carbon nanotube, mesophase carbon microbead (MCMB) or carbonaceous microsphere (CMS), soft carbon, hard carbon, and combinations thereof. All of these materials contain graphite crystallites that are composed of layers of graphene planes stacked or bonded together via van der Waals forces. In natural graphite, multiple stacks of graphene planes, with the graphene plane orientation varying from stack to stack, are clustered together. In carbon fibers, the graphene planes are usually oriented along a preferred direction. Generally speaking, soft carbons are carbonaceous materials obtained from carbonization of liquid-state, aromatic molecules. Their aromatic ring or graphene structures are more or less parallel to one another, enabling further graphitization. Hard carbons are carbonaceous materials obtained from aromatic solid materials (e.g., polymers, such as phenolic resin and polyfurfuryl alcohol). Their graphene structures are relatively randomly oriented and, hence, further graphitization is difficult to achieve even at a temperature higher than 2,500° C. But, graphene sheets do exist in these carbons.

Fluorinated graphene or graphene fluoride is herein used as an example of the halogenated graphene material group. There are two different approaches that have been followed to produce fluorinated graphene: (1) fluorination of pre-synthesized graphene: This approach entails treating graphene prepared by mechanical exfoliation or by CVD growth with fluorinating agent such as XeF₂, or F-based plasmas; (2) Exfoliation of multilayered graphite fluorides: Both mechanical exfoliation and liquid phase exfoliation of graphite fluoride can be readily accomplished [F. Karlicky, et al. “Halogenated Graphenes: Rapidly Growing Family of Graphene Derivatives” ACS Nano, 2013, 7 (8), pp 6434-6464].

Interaction of F₂ with graphite at high temperature leads to covalent graphite fluorides (CF) or (C₂F)ₙ, while at low temperatures graphite intercalation compounds (GIC) CₓF (2≤x≤24) form. In (CF) carbon atoms are sp3-hybridized and thus the fluorocarbon layers are corrugated consisting of trans-linked cyclohexane chairs. In (C₂F)ₙ only half of the C atoms are fluorinated and every pair of the adjacent carbon sheets are linked together by covalent C—C bonds. Systematic studies on the fluorination reaction showed that the resulting F/C ratio is largely dependent on the fluorination temperature, the partial pressure of the fluorine in the fluorinating gas, and physical characteristics of the graphite precursor, including the degree of graphitization, particle size, and specific surface area. In addition to fluorine (F₂), other fluorinating agents may be used, although most of the available literature involves fluorination with F₂ gas, sometimes in presence of fluorides.

For exfoliating a layered precursor material to the state of individual single graphene layers or few-layers, it is necessary to overcome the attractive forces between adjacent layers and to further stabilize the layers. This may be achieved by either covalent modification of the graphene surface by functional groups or by non-covalent modification using specific solvents, surfactants, polymers, or donor-acceptor aromatic molecules. The process of liquid phase exfoliation includes ultra-sonic treatment of a graphite fluoride in a liquid medium to produce graphene fluoride sheets dispersed in the liquid medium. The resulting dispersion can be directly used in the graphene deposition of polymer component surfaces.

The nitrogenation of graphene can be conducted by exposing a graphene material, such as graphene oxide, to ammonia at high temperatures (200-400° C.). Nitrogenated graphene could also be formed at lower temperatures by a hydrothermal method; e.g. by sealing GO and ammonia in an autoclave and then increased the temperature to 150-250° C. Other methods to synthesize nitrogen doped graphene include nitrogen plasma treatment on graphene, arc-discharge between graphite electrodes in the presence of ammonia, ammonolysis of graphene oxide under CVD conditions, and hydrothermal treatment of graphene oxide and urea at different temperatures.

For the purpose of defining the claims of the instant application, NGPs or graphene materials include discrete sheets/platelets of single-layer and multi-layer (typically less than 10 layers, the few-layer graphene) pristine graphene, graphene oxide, reduced graphene oxide (RGO), graphene fluoride, graphene chloride, graphene bromide, graphene iodide, hydrogenated graphene, nitrogenated graphene, chemically functionalized graphene, doped graphene (e.g. doped by B or N). Pristine graphene has essentially 0% oxygen. RGO typically has an oxygen content of 0.001%-5% by weight. Graphene oxide (including RGO) can have 0.001%-50% by weight of oxygen. Other than pristine graphene, all the graphene materials have 0.001%-50% by weight of non-carbon elements (e.g. O, H, N, B, F, Cl, Br, I, etc.). These materials are herein referred to as non-pristine graphene materials. The presently disclosed graphene can contain pristine or non-pristine graphene and the disclosed method allows for this flexibility. These graphene sheets all can be chemically functionalized.

Graphene sheets have a significant proportion of edges that correspond to the edge planes of graphite crystals. The carbon atoms at the edge planes are reactive and must contain some heteroatom or group to satisfy carbon valency. Further, there are many types of functional groups (e.g. hydroxyl and carboxylic) that are naturally present at the edge or surface of graphene sheets produced through chemical or electrochemical methods. Many chemical function groups (e.g. —NH₂, etc.) can be readily imparted to graphene edges and/or surfaces using methods that are well-known in the art.

In one preferred embodiment, the resulting functionalized graphene sheets (NGP) may broadly have the following formula(e): [NGP]-Rₘ, wherein m is the number of different functional group types (typically between 1 and 5), R is selected from SO₃H, COOH, NH₂, OH, R′CHOH, CHO, CN, COCl, halide, COSH, SH, COOR′, SR′, SiR′₃, Si(—OR′—)_{y}R′₃-y, Si(—O—SiR′₂—)OR′, R″, Li, AlR′₂, Hg—X, TlZ₂ and Mg—X; wherein y is an integer equal to or less than 3, R′ is hydrogen, alkyl, aryl, cycloalkyl, or aralkyl, cycloaryl, or poly(alkylether), R″ is fluoroalkyl, fluoroaryl, fluorocycloalkyl, fluoroaralkyl or cycloaryl, X is halide, and Z is carboxylate or trifluoroacetate.

For NGPs to be effective reinforcement fillers in epoxy resin, the function group —NH₂ is of particular interest. For example, a commonly used curing agent for epoxy resin is diethylenetriamine (DETA), which has three —NH₂ groups. If DETA is included in the impacting chamber, one of the three —NH₂ groups may be bonded to the edge or surface of a graphene sheet and the remaining two un-reacted —NH₂ groups will be available for reacting with epoxy resin later. Such an arrangement provides a good interfacial bonding between the NGP (graphene sheets) and the matrix resin of a composite material.

Other useful chemical functional groups or reactive molecules may be selected from the group consisting of amidoamines, polyamides, aliphatic amines, modified aliphatic amines, cycloaliphatic amines, aromatic amines, anhydrides, ketimines, diethylenetriamine (DETA), triethylene-tetramine (TETA), tetraethylene-pentamine (TEPA), hexamethylenetetramine, polyethylene polyamine, polyamine epoxy adduct, phenolic hardener, non-brominated curing agent, non-amine curatives, and combinations thereof. These functional groups are multi-functional, with the capability of reacting with at least two chemical species from at least two ends. Most importantly, they are capable of bonding to the edge or surface of graphene using one of their ends and, during subsequent epoxy curing stage, are able to react with epoxide or epoxy resin at one or two other ends.

The above-described [NGP]-Rₘ may be further functionalized. The resulting graphene sheets include compositions of the formula: [NGP]-Aₘ, where A is selected from OY, NHY, O═C—OY, P═C—NR′Y, O═C—SY, O═C—Y, —CR′1-OY, N′Y or C′Y, and Y is an appropriate functional group of a protein, a peptide, an amino acid, an enzyme, an antibody, a nucleotide, an oligonucleotide, an antigen, or an enzyme substrate, enzyme inhibitor or the transition state analog of an enzyme substrate or is selected from R′—OH, R′—NR′₂, R′SH, R′CHO, R′CN, R′X, R′N⁺(R′)₃X⁻, R′SiR′₃, R′Si(—OR′—)_{y}R′_{3-y}, R′Si(—O—SiR′₂—)OR′, R′—R″, R′—N—CO, (C₂H₄O—)_{w}H, (—C₃H₆O—)_{w}H, (—C₂H₄O)_{w}—R′, (C₃H₆O)_{w}—R′, R′, and w is an integer greater than one and less than 200. CNTs may be similarly functionalized.

The NGPs and conductive additives (e.g. carbon nanofibers) may also be functionalized to produce compositions having the formula: [NGP]-[R′-A]ₘ, where m, R′ and A are as defined above. The compositions of the disclosure also include NGPs upon which certain cyclic compounds are adsorbed. These include compositions of matter of the formula: [NGP]-[X—Rₐ]ₘ, where a is zero or a number less than 10, X is a polynuclear aromatic, polyheteronuclear aromatic or metallopolyheteronuclear aromatic moiety and R is as defined above. Preferred cyclic compounds are planar. More preferred cyclic compounds for adsorption are porphyrins and phthalocyanines. The adsorbed cyclic compounds may be functionalized. Such compositions include compounds of the formula, [NGP]-[X-Aₐ]ₘ, where m, a, X and A are as defined above.

The functionalized NGPs of the instant disclosure can be directly prepared by sulfonation, electrophilic addition to deoxygenated graphene platelet surfaces, or metallization. The graphene platelets can be processed prior to being contacted with a functionalizing agent. Such processing may include dispersing the graphene platelets in a solvent. In some instances, the platelets or may then be filtered and dried prior to contact. One particularly useful type of functional group is the carboxylic acid moieties, which naturally exist on the surfaces of NGPs if they are prepared from the acid intercalation route discussed earlier. If carboxylic acid functionalization is needed, the NGPs may be subjected to chlorate, nitric acid, or ammonium persulfate oxidation.

Carboxylic acid functionalized graphene sheets or platelets are particularly useful because they can serve as the starting point for preparing other types of functionalized NGPs. For example, alcohols or amides can be easily linked to the acid to give stable esters or amides. If the alcohol or amine is part of a di- or poly-functional molecule, then linkage through the O- or NH-leaves the other functionalities as pendant groups. These reactions can be carried out using any of the methods developed for esterifying or aminating carboxylic acids with alcohols or amines as known in the art. Examples of these methods can be found in G. W. Anderson, et al., J. Amer. Chem. Soc. 86, 1839 (1964), which is hereby incorporated by reference in its entirety. Amino groups can be introduced directly onto graphitic platelets by treating the platelets with nitric acid and sulfuric acid to obtain nitrated platelets, then chemically reducing the nitrated form with a reducing agent, such as sodium dithionite, to obtain amino-functionalized platelets.

The graphene dispersions produced may be further added with an acid, a metal salt, an oxidizer, or a combination thereof to prepare a more reactive dispersion for use in the graphene coating of a polymer component. An optional adhesive resin may also be added. In these situations, the surface cleaning, etching, and graphene coating can be accomplished in one step. One may simply dip a polymer component into the graphene solution for several seconds to several minutes (preferably 5 seconds to 15 minutes) and then retreat the polymer component from the graphene-liquid dispersion. Upon removal of the liquid (e.g. via natural or forced vaporization), graphene sheets are naturally coated on and bonded to polymer component surfaces.

In certain embodiments, functionalized graphene sheets and/or conductive filler may be pre-coated or decorated with nanoscaled particles of a catalytic metal, which can catalyze the subsequent chemical metallization process. This catalytic metal is preferably in the form of discrete nanoscaled particles or coating having a diameter or thickness from 0.5 nm to 100 nm and is preferably selected from cobalt, nickel, copper, iron, manganese, tin, zinc, lead, bismuth, silver, gold, palladium, platinum, an alloy thereof, or a combination thereof. The catalytic metal may alternatively be initially in a precursor form (e.g. as a metal salt) which is later converted into nanoscaled metal deposited on graphene surfaces.

Thus, the disclosure also provides a graphene dispersion (or graphene/conductive filler dispersion) for use in metallization of a fiber, yam, or fabric surface. The graphene dispersion comprises comprising multiple graphene sheets and a conductive filler dispersed in a liquid medium wherein the multiple graphene sheets contain single-layer or few-layer graphene sheets selected from a pristine graphene material having essentially zero % of non-carbon elements, or a non-pristine graphene material having 0.001% to 25% by weight of non-carbon elements wherein said non-pristine graphene is selected from graphene oxide, reduced graphene oxide, graphene fluoride, graphene chloride, graphene bromide, graphene iodide, hydrogenated graphene, nitrogenated graphene, doped graphene, chemically functionalized graphene, or a combination thereof, and wherein the dispersion further contains one or multiple species selected from (i) an adhesive resin dissolved or dispersed in the liquid medium, wherein an adhesive-to-graphene weight ratio is from 1/5000 to 1/10; (ii) an etchant selected from an acid, an oxidizer, a metal salt, or a combination thereof; (iii) nanoscaled particles or coating of a catalytic metal, having a diameter or thickness from 0.5 nm to 100 nm, selected from cobalt, nickel, copper, iron, manganese, tin, zinc, lead, bismuth, silver, gold, palladium, platinum, an alloy thereof, or a combination thereof, or (iv) a combination thereof.

Once graphene sheets are bonded on a surface of a fiber, yam, or fabric, step (c) in the disclosed method may contain immersing the graphene/conductive filler-bonded fiber, yarn, or fabric in a metallizing bath for electroless plating of metals (chemical metallization). It is highly surprising that graphene surfaces per se (even without transition metal or noble metal) are capable of promoting conversion of some metal salts to metal deposited on graphene surfaces. This would obviate the need to use expensive noble metals (e.g. palladium or platinum) as nuclei for subsequent chemical growth of metal crystals, as required of the prior art process.

The high electrical conductivity and high specific surface areas of the deposited graphene sheets (capable of covering a wide surface area of a fiber, yarn, or fabric) enable electro-plating of metal layer(s) on graphene-coated fiber, yarn, or fabric surfaces. Graphene sheets, deposited on polymer component surfaces, are also found to significantly enhance the strength, hardness, durability, and scratch resistance of the deposited metal layer.

Alternatively, one may choose to use physical vapor deposition, sputtering, plasma deposition, etc. to accomplish the final metallization procedure.

Thus, the disclosed process produces a surface-metalized fiber, yarn, or fabric comprising a fiber, yarn, or fabric having a surface, a first layer of multiple graphene sheets and a conductive filler coated on the fiber, yarn, or fabric surface, and a second layer of a plated metal deposited on the first layer, wherein the multiple graphene sheets (functionalized or un-functionalized) contain single-layer graphene sheets or few-layer graphene sheets (2-10 graphene planes) wherein the multiple graphene sheets are bonded to the fiber, yarn, or fabric surface with or without an adhesive resin.

The first layer (graphene layer) typically has a thickness from 0.34 nm to 20 μm (preferably from 1 nm to 1 μm and further preferably from 1 nm to 100 nm). The second layer preferably has a thickness from 0.5 nm to 1.0 mm, and more preferably from 1 nm to 10 μm. The doped graphene preferably contains N-doped, boron-doped, phosphorus-doped graphene, or a combination thereof. The graphene sheets contain a pristine graphene and the first layer contains an adhesive resin that chemically bonds the graphene sheets to the polymer component surface. In certain alternative embodiments, the graphene sheets contain a non-pristine graphene material having a content of non-carbon elements from 0.01% to 20% by weight and the non-carbon elements include an element selected from oxygen, fluorine, chlorine, bromine, iodine, nitrogen, hydrogen, or boron.

The fiber, yarn, or fabric may contain a filamentary form of a plastic, a rubber, a thermoplastic elastomer, a polymer matrix composite, a rubber matrix composite, or a combination thereof. In certain embodiments, the fiber, yarn, or fabric contains a thermoplastic, a thermoset resin, an interpenetrating network, a rubber, a thermoplastic elastomer, a natural polymer, or a combination thereof. In certain preferred embodiments, the polymer component contains a plastic selected from acrylonitrile-butadiene-styrene copolymer (ABS), styrene-acrylonitrile copolymer (SAN), polycarbonate, polyamide or nylon, polystyrene, polyacrylate, polyethylene, polypropylene, polyacetal, polyester, polyether, polyether sulfone, poly ether ether ketone (PEEK), poly sulfone, polyphenylene oxide (PPO), polyvinyl chloride (PVC), polyimide, polyamide imide, polyurethane, polyurea, or a combination thereof.

In the surface-metalized fiber, yam, or fabric, the plated metal is preferably selected from copper, nickel, aluminum, chromium, tin, zinc, titanium, silver, gold, an alloy thereof, or a combination thereof.

The graphene sheets may be further decorated with nanoscaled particles or coating (having a diameter or thickness from 0.5 nm to 100 nm) of a catalytic metal selected from cobalt, nickel, copper, iron, manganese, tin, zinc, lead, bismuth, silver, gold, palladium, platinum, an alloy thereof, or a combination thereof, and wherein the catalytic metal is different in chemical composition than the plated metal. The catalytic metal particles or coating are covered by at least a layer of plated metal

In certain embodiments, the fiber, yarn, or fabric surface, prior to being deposited with the first layer of graphene sheets, contains only small openings or pores having a diameter or a depth <0.1 μm.

In certain embodiments, the multiple graphene sheets are bonded to the fiber, yarn, or fabric surface with an adhesive resin having an adhesive-to-graphene weight ratio from 1/5000 to 1/10, preferably from 1/1000 to 1/100.

The following examples are used to illustrate some specific details about the best modes of practicing the instant disclosure and should not be construed as limiting the scope of the disclosure.

### Example 1: Graphene Oxide from Sulfuric Acid Intercalation and Exfoliation of MCMBs

MCMB (mesocarbon microbeads) were supplied by China Steel Chemical Co. This material has a density of about 2.24 g/cm³ with a median particle size of about 16 μm. MCMBs (10 grams) were intercalated with an acid solution (sulfuric acid, nitric acid, and potassium permanganate at a ratio of 4:1:0.05) for 48 hours. Upon completion of the reaction, the mixture was poured into deionized water and filtered. The intercalated MCMBs were repeatedly washed in a 5% solution of HCl to remove most of the sulfate ions. The sample was then washed repeatedly with deionized water until the pH of the filtrate was neutral. The slurry was dried and stored in a vacuum oven at 60° C. for 24 hours. The dried powder sample was placed in a quartz tube and inserted into a horizontal tube furnace pre-set at a desired temperature, 800° C.-1,100° C. for 30-90 seconds to obtain graphene sheets. A quantity of graphene sheets was mixed with water and ultrasonicated at 60-W power for 10 minutes to obtain a graphene dispersion.

A small amount was sampled out, dried, and investigated with TEM, which indicated that most of the NGPs were between 1 and 10 layers. The oxygen content of the graphene powders (GO or RGO) produced was from 0.1% to approximately 25%, depending upon the exfoliation temperature and time.

Several graphene dispersions were separately added with a variety of acids, metal salts, and oxidizer species for use in the metallization of polymers.

### Example 2: Oxidation and Exfoliation of Natural Graphite

Graphite oxide was prepared by oxidation of graphite flakes with sulfuric acid, sodium nitrate, and potassium permanganate at a ratio of 4:1:0.05 at 30° C. for 48 hours, according to the method of Hummers [U.S. Pat. No. 2,798,878, Jul. 9, 1957]. Upon completion of the reaction, the mixture was poured into deionized water and filtered. The sample was then washed with 5% HCl solution to remove most of the sulfate ions and residual salt and then repeatedly rinsed with deionized water until the pH of the filtrate was approximately 4. The intent was to remove all sulfuric and nitric acid residue out of graphite interstices. The slurry was dried and stored in a vacuum oven at 60° C. for 24 hours.

The dried, intercalated (oxidized) compound was exfoliated by placing the sample in a quartz tube that was inserted into a horizontal tube furnace pre-set at 1,050° C. to obtain highly exfoliated graphite. The exfoliated graphite was dispersed in water along with a 1% surfactant at 45° C. in a flat-bottomed flask and the resulting suspension was subjected to ultrasonication for a period of 15 minutes to obtain dispersion of graphene oxide (GO) sheets.

### Example 3: Preparation of Pristine Graphene

Pristine graphene sheets were produced by using the direct ultrasonication or liquid-phase exfoliation process. In a typical procedure, five grams of graphite flakes, ground to approximately 20 μm in sizes, were dispersed in 1,000 mL of deionized water (containing 0.1% by weight of a dispersing agent, Zonyl® FSO from DuPont) to obtain a suspension. An ultrasonic energy level of 85 W (Branson S450 Ultrasonicator) was used for exfoliation, separation, and size reduction of graphene sheets for a period of 15 minutes to 2 hours. The resulting graphene sheets were pristine graphene that had never been oxidized and were oxygen-free and relatively defect-free.

### Examples 4: Preparation of Graphene Fluoride

Several processes have been used by us to produce GF, but only one process is herein described as an example. In a typical procedure, highly exfoliated graphite (HEG) was prepared from intercalated compound C₂F.xClF₃. HEG was further fluorinated by vapors of chlorine trifluoride to yield fluorinated highly exfoliated graphite (FHEG). A pre-cooled Teflon reactor was filled with 20-30 mL of liquid pre-cooled ClF₃, and then the reactor was closed and cooled to liquid nitrogen temperature. Subsequently, no more than 1 g of HEG was put in a container with holes for ClF₃ gas to access the reactor. After 7-10 days, a gray-beige product with approximate formula C₂F was formed. GF sheets were then dispersed in halogenated solvents to form suspensions.

### Example 5: Preparation of Nitrogenated Graphene

Graphene oxide (GO), synthesized in Example 2, was finely ground with different proportions of urea and the pelletized mixture heated in a microwave reactor (900 W) for 30 s. The product was washed several times with deionized water and vacuum dried. In this method graphene oxide gets simultaneously reduced and doped with nitrogen. The products obtained with graphene/urea mass ratios of 1/0.5, 1/1 and 1/2 are designated as N-1, N-2 and N-3 respectively and the nitrogen contents of these samples were 14.7, 18.2 and 17.5 wt. % respectively as determined by elemental analysis. These nitrogenated graphene sheets remain dispersible in water.

### Example 6: Graphene-Bonded/Activated Polypropylene Fibers (PP Monofilaments)

A first set of several PP fibers were immersed for 3 minutes at 70° C. in an etching solution consisting of 4 M H₂SO₄ and 3.5 M CrO₃. The fibers were rinsed with water. On a separate basis, a second set of PP fibers were used without etching.

The two sets of specimens were immersed for a time period of 30 seconds at 40° C. in a RGO-water solution prepared in Example 1 and then removed from the solution and dried in air. Subsequently, the RGO-bonded PP fibers were copper-plated in a sulfuric acid-containing copper electrolyte. We have surprisingly observed that the presently disclosed method enables successful metallization of PP fibers and a variety of polymer fibers (e.g. nylon fibers and PET fibers) without etching. The bonded metal layers mediated by graphene sheets perform equally well in terms of surface hardness, scratch resistance, and durability against heating/cooling cycles

### Comparative Example 6a: Pd/Sn-Activated PP Fibers

A first set of several PP fibers were immersed for 3 minutes at 70° C. in an etching solution consisting of 4 M H₂SO₄ and 3.5 M CrO₃. The fibers were rinsed with water. On a separate basis, a second set of PP fibers were used without etching.

The two sets of specimens were immersed for a time period of 5 minutes at 40° C. in a Pd/Sn colloid-containing solution which contains 250 mg/L palladium, 10 g/L tin(Ill) and 110 g/L HCl. Subsequently, the specimens were rinsed in water and copper-plated in a sulfuric acid-containing copper electrolyte. We have observed that, without heavy etching, PP fiber surfaces could not be properly (evenly) metallized even when some significant amount of expensive rare metal (e.g. Pd) was implemented on etched surfaces.

### Example 7: Graphene-Bonded/Activated Cotton Fabrics (Containing Natural Polymer Fibers)

A first set of several pieces of cotton fabrics were immersed for 3 minutes at 70° C. in an etching solution consisting of 4 M H₂SO₄ and 3.5 M CrO₃. These fabrics were rinsed with water. On a separate basis, a second set of several fabrics were used without etching.

Following this, the cotton fabrics were spray-coated with a pristine graphene-adhesive solution containing 5% by weight graphene sheets and 0.01% by weight epoxy resin. Upon removal of the liquid medium (acetone) and cured at 150° C. for 15 minutes, graphene sheets were well bonded to fabric surfaces.

After this treatment, the graphene-bonded cotton fabrics were subjected to electro-chemical nickel plating. For this, the articles were treated for 15 minutes in a Watts electrolyte, containing 1.2 M NiSO₄.7H₂O, 0.2 M NiCl₂O.6H₂O and 0.5 M H₃BO₃. The initial current was 0.3 A/dm², and the nickel plating was carried out at 40° C.

### Comparative Example 7a: Sulfide-Activated Cotton Fabrics

A first set of several pieces of cotton fabrics were immersed for 3 minutes at 70° C. in an etching solution consisting of 4 M H₂SO₄ and 3.5 M CrO₃. The fabrics were rinsed with water. On a separate basis, a second set of several pieces of fabrics were used without etching.

Following this, the fabrics were treated for 30 seconds in an ammonia solution with 0.5 M CuSO_{4.5}H₂O having a pH value of 9.5 and a temperature of 20° C. The fabrics were then submerged for 20 seconds in distilled water and, subsequently, for 30 seconds treated with a sulfide solution, containing 0.1 M Na₂S₂ at 20° C. After this treatment, the fabrics were again washed in cold water. This was followed by electro-chemical nickel plating. For this, the fabrics were treated for 15 minutes in a Watts electrolyte, containing 1.2 M NiSO₄.7H₂O, 0.2 M NiCl₂.6H₂O and 0.5 M H₃BO₃. The initial current was 0.3 A/dm², and the nickel plating was carried out at 40° C. We have observed that, without heavy etching, cotton fabric surfaces could not be evenly metallized using the sulfide seeding approach. In contrast, the instant graphene-mediation approach enables successful plating of practically all kinds of metals on not just cotton fabrics but any other types of polymer fibers, yarns, and fabrics.

### Example 8: Metallization of Graphene-Bonded Glass Fiber Yarns

Catalytic metal can be deposited onto graphene surfaces using a variety of processes: physical vapor deposition, sputtering, chemical vapor deposition, chemical reduction/oxidation, electrochemical reduction/oxidation, etc. In this example, Co is used as a representative catalytic metal and chemical oxidation/reduction from solution is used for deposition of nanoparticles on graphene surfaces.

A cobalt salt solution was used as the metal salt solution. The aqueous cobalt (II) salt solution contains 1 to 10 g/L CoSO₄.7H₂O and one oxidizer, hydrogen peroxide. Graphene oxide sheets were dispersed in the solution to form a dispersion. Heating of such a dispersion enabled at least part of the cobalt (II) to be oxidized by H₂O₂ into cobalt (III), which was deposited on graphene surfaces upon further heating. Glass fiber yarns were dipped into this solution and then retreated from this solution to obtain graphene-coated glass fiber yarns. The electrolytic direct metallization of the subsequently dried graphene-coated glass fiber yarns was then allowed to proceed. The glass fiber yarn surface was plated in a nickel bath, wherein an initial current density of 0.3 A/dm² was used for electro-chemical nickel plating which later was increased to 3 A/dm². Electro-chemical nickel plating was conducted in a Watts electrolyte at 30 to 40° C. for a treatment time of 10 to 15 minutes. The Watts electrolyte contains 1.2 M NiSO₄.7H₂O, 0.2 M NiCl₂.6H₂O and 0.5 M H₃BO₃.

### Example 9: Functionalized Graphene-Bonded Kevlar Fiber Yarns

A first set of several Kevlar fiber yarns (from Du Pont) were immersed for 3 minutes at 70° C. in an etching solution consisting of 4 M H₂SO₄ and 3.5 M CrO₃. The yarns were rinsed with water. Separately, a second set of Kevlar yarns were used without etching.

Subsequently, the Kevlar yarns were dipped into a functionalized graphene-adhesive dispersion containing 5% by weight of graphene sheets and 0.01% by weight of epoxy resin or polyurethane. Chemical functional groups involved in this study include an azide compound (2-Azidoethanol), alkyl silane, hydroxyl group, carboxylic group, amine group, sulfonate group (—SO₃H), and diethylenetriamine (DETA). These functionalized graphene sheets are supplied from Taiwan Graphene Co., Taipei, Taiwan. Upon removal of the liquid medium (acetone) and cured at 150° C. for 15 minutes, graphene sheets were well bonded to Kevlar fiber surfaces.

After this treatment, the graphene-bonded Kevlar fibers were subjected to chemical nickel plating or chemical copper plating. For nickel plating, the functionalized graphene-bonded fibers were treated for 15 minutes in a chemical plating solution containing 1.2 M NiSO₄.7H₂O at 40° C. For Cu plating, the functionalized graphene-bonded plastic parts were dipped in an ammonia solution with 0.5 M CuSO₄. H₂O having a pH value of 9.5 and a temperature of 20° C. for 30 seconds.

The present disclosure has the following unexpected advantages:
1. Even without using chromic acid or chromosulfuric acid, strong adhesion between the deposited metal layers and the lightly etched fiber/yam/fabric surfaces can be achieved via functionalized graphene sheet mediation. These well-bonded metal layers show a high temperature cycling resistance and survive all the customary temperature cycling shocks.
2. A wide variety of chemical functional groups can be attached to the edges or surfaces of mediating graphene sheets and optional conductive filler (e.g. carbon nanotubes, metal nanowires, etc.) that enable rapid metallization of a broad array of fibers, yarns, and fabrics. The graphene sheets that exhibit a negative Zeta potential value in an intended liquid medium are particularly effective in promoting metallization of a fiber, yarn, or fabric.
3. The disclosed process can be conducted under very mild conditions requiring only a short period of time. Optimal results are also achievable without the repetition of the process steps commonly required of prior art processes.
4. High-quality metal layers can be deposited on fiber, yarn, or fabric surfaces without heavy capital investment and large material consumption. Further, the process can be controlled in a functionally secure and simple manner which ultimately affects the quality of the metal layers.
5. A surprisingly wide variety of fiber, yam, or fabric materials, including not just polymer, but also glass, ceramic, and carbon fibers/yarns/fabrics can be effectively metallized. In contrast, only a limited number of fibers/yarns/fabrics could be satisfactorily metallized with prior art processes.
6. Since etching of the plastic surface at high temperatures is not necessary, energy savings can be achieved. Since only mild etching conditions are required where necessary in rare cases (e.g. highly smooth ultrahigh molecular weight PE fiber surfaces), a broader array of benign etching solutions can be used; obviating the need to use environmentally restricted chemicals.
7. The presently disclosed process or method can involve only two steps: contacting fiber/yam/fabric surface with a graphene dispersion (e.g. a dipping step) and contacting the graphene-bonded surface with a chemical plating or electrochemical plating solution (e.g. another fast dipping step). In contrast, the prior art process required many steps: pretreatment, chemical etching, activation, chemical metallization, and electrolytic deposition of multiple metal layers (hence, further multiple steps).

We claim:

1. A surface-metalized fiber, yarn, or fabric comprising:
(a) a fiber, fiber yarn, or fiber fabric having a surface;
(b) a graphene layer having a thickness from 0.34 nm to 20 μm and comprising multiple graphene sheets and an optional conducive filler coated on or bonded to said surface, with or without using an adhesive resin, to form a graphene-coated fiber, fiber yarn, or fiber fabric; and
(c) a metal layer comprising a plated metal deposited on said graphene-coated fiber, fiber yarn, or fiber fabric;
wherein said multiple graphene sheets contain single-layer or few-layer graphene sheets selected from a pristine graphene material having essentially zero % of non-carbon elements, or a non-pristine graphene material having 0.001% to 25% by weight of non-carbon elements wherein said non-pristine graphene is selected from graphene oxide, reduced graphene oxide, graphene fluoride, graphene chloride, graphene bromide, graphene iodide, hydrogenated graphene, nitrogenated graphene, doped graphene, chemically functionalized graphene, or a combination thereof.

2. The surface-metalized fabric of claim 1, wherein each of the two primary surfaces of said fabric is coated with or bonded to a graphene layer having a thickness from 0.34 nm to 50 μm and comprising multiple graphene sheets and an optional conducive filler and wherein a metal layer comprising a plated metal is deposited on the graphene layer of each of the two primary surfaces.

3. The surface-metalized fiber, yarn, or fabric of claim 1, wherein said conductive filler is selected from metal nanowires, carbon fibers, carbon nanofibers, carbon nanotubes, carbon-coated fibers, conductive polymer fibers, nanofibers or nanowires of SnO₂, ZnO₂, In₂O₃, or indium-tin oxide (ITO), a conductive polymer not in a fiber form, or a combination thereof.

4. The surface-metalized fiber, yarn, or fabric of claim 3, wherein said metal nanowires are selected from nanowires of silver (Ag), gold (Au), copper (Cu), platinum (Pt), zinc (Zn), cadmium (Cd), cobalt (Co), molybdenum (Mo), aluminum (Al), or a combination thereof.

5. The surface-metalized fiber, yarn, or fabric of claim 3, wherein said conductive polymer is selected from the group consisting of polydiacetylene, polyacetylene (PAc), polypyrrole (PPy), polyaniline (PAni), polythiophene (PTh), polyisothionaphthene (PITN), polyheteroarylenvinylene (PArV), in which the heteroarylene group is selected from thiophene, furan or pyrrole, poly-p-phenylene (PpP), polyphthalocyanine (PPhc) and the like, and their derivatives, and combinations thereof.

6. The surface-metalized fiber, yarn, or fabric of claim 1, wherein said graphene sheets contain a functional group attached thereto to make the graphene sheets in a liquid medium exhibit a negative Zeta potential from −55 mV to −0.1 mV.

7. The surface-metalized fiber, yarn, or fabric of claim 1, wherein said chemically functionalized graphene comprises graphene sheets having a chemical functional group selected from alkyl or aryl silane, alkyl or aralkyl group, hydroxyl group, carboxyl group, carboxylic group, amine group, sulfonate group (—SO₃H), aldehydic group, quinoidal, fluorocarbon, or a combination thereof.

8. The surface-metalized fiber, yarn, or fabric of claim 1, wherein said chemically functionalized graphene comprises graphene sheets having a chemical functional group selected from a derivative of an azide compound selected from the group consisting of 2-azidoethanol, 3-azidopropan-1-amine, 4-(2-azidoethoxy)-4-oxobutanoic acid, 2-azidoethyl-2-bromo-2-methylpropanoate, chlorocarbonate, azidocarbonate, dichlorocarbene, carbene, aryne, nitrene, (R−)-oxycarbonyl nitrenes, where R=any one of the following groups, 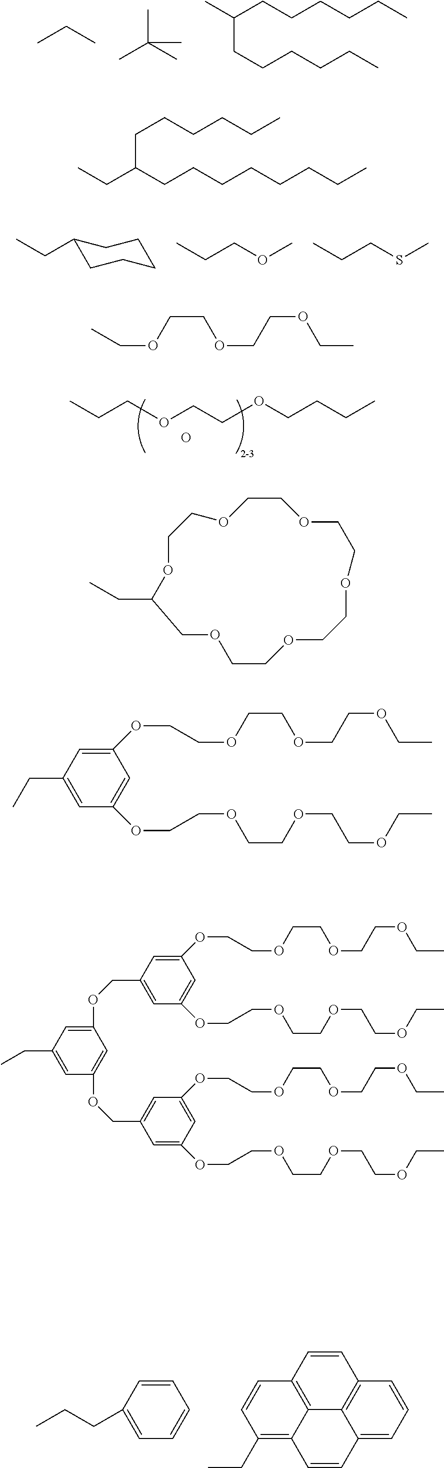
and combinations thereof.

9. The surface-metalized fiber, yarn, or fabric of claim 1, wherein said chemically functionalized graphene comprises graphene sheets having a chemical functional group selected from an oxygenated group selected from the group consisting of hydroxyl, peroxide, ether, keto, and aldehyde.

10. The surface-metalized fiber, yarn, or fabric of claim 1, wherein said chemically functionalized graphene comprises graphene sheets having a chemical functional group selected from the group consisting of —SO₃H, —COOH, —NH₂, —OH, —R′CHOH, —CHO, —CN, —COCl, halide, —COSH, —SH, —COOR′, —SR′, —SiR′₃, —Si(—OR′—)_{y}R′₃-y, —Si(—O—SiR′₂—)OR′, —R″, Li, AlR′₂, Hg—X, TlZ₂ and Mg—X; wherein y is an integer equal to or less than 3, R′ is hydrogen, alkyl, aryl, cycloalkyl, or aralkyl, cycloaryl, or poly(alkylether), R″ is fluoroalkyl, fluoroaryl, fluorocycloalkyl, fluoroaralkyl or cycloaryl, X is halide, and Z is carboxylate or trifluoroacetate, and combinations thereof.

11. The surface-metalized fiber, yarn, or fabric of claim 1, wherein said chemically functionalized graphene comprises graphene sheets having a chemical functional group selected from the group consisting of amidoamines, polyamides, aliphatic amines, modified aliphatic amines, cycloaliphatic amines, aromatic amines, anhydrides, ketimines, diethylenetriamine (DETA), triethylene-tetramine (TETA), tetraethylene-pentamine (TEPA), polyethylene polyamine, polyamine epoxy adduct, phenolic hardener, non-brominated curing agent, non-amine curatives, and combinations thereof.

12. The surface-metalized fiber, yarn, or fabric of claim 1, wherein said chemically functionalized graphene comprises graphene sheets having a chemical functional group selected from OY, NHY, O═C—OY, P═C—NR′Y, O═C—SY, O═C—Y, —CR′1-OY, N′Y or C′Y, and Y is a functional group of a protein, a peptide, an amino acid, an enzyme, an antibody, a nucleotide, an oligonucleotide, an antigen, or an enzyme substrate, enzyme inhibitor or the transition state analog of an enzyme substrate or is selected from R′—OH, R′—NR′₂, R′SH, R′CHO, R′CN, R′X, R′N′(R′)₃X⁻, R′SiR′₃, R′Si(—OR′—)_{y}R′_{3-y}, R′Si(—O—SiR′₂—)OR′, R′—R″, R′—N—CO, (C₂H₄O—)_{w}H, (—C₃H₆O—)_{w}H, (—C₂H₄O)_{w}—R′, (C₃H₆O)_{w}—R′, R′, and w is an integer greater than one and less than 200.

13. The surface-metalized fiber, yarn, or fabric of claim 1, wherein said metal layer has a thickness from 0.5 nm to 1.0 mm.

14. The surface-metalized fiber, yarn, or fabric of claim 1, wherein said first layer contains an adhesive resin that chemically bonds said graphene sheets and said conductive filler to said polymer component surface.

15. The surface-metalized fiber, yarn, or fabric of claim 14, wherein said adhesive resin includes an ester resin, a neopentyl glycol (NPG), ethylene glycol (EG), isophthalic acid, a terephthalic acid, a urethane resin, a urethane ester resin, an acrylic resin, an acrylic urethane resin, or a combination thereof.

16. The surface-metalized fiber, yarn, or fabric of claim 14, wherein said adhesive resin contains a curing agent and/or a coupling agent in an amount of 1 to 30 parts by weight based on 100 parts by weight of the adhesive resin.

17. The surface-metalized fiber, yarn, or fabric of claim 14, wherein said adhesive resin contains a thermally curable resin containing a polyfunctional epoxy monomer selected from diglycerol tetraglycidyl ether, dipentaerythritol tetraglycidyl ether, sorbitol polyglycidyl ether, polyglycerol polyglycidyl ether, pentaerythritol polyglycidyl ether, or a combination thereof.

18. The surface-metalized fiber, yarn, or fabric of claim 14, wherein said adhesive resin contains a thermally curable resin containing a bi- or tri-functional epoxy monomer selected from the group consisting of trimethylolethane triglycidyl ether, trimethylolmethane triglycidyl ether, trimethylolpropane triglycidyl ether, triphenylolmethane triglycidyl ether, trisphenol triglycidyl ether, tetraphenylol ethane triglycidyl ether, tetraglycidyl ether of tetraphenylol ethane, p-aminophenol triglycidyl ether, 1,2,6-hexanetriol triglycidyl ether, glycerol triglycidyl ether, diglycerol triglycidyl ether, glycerol ethoxylate triglycidyl ether, castor oil triglycidyl ether, propoxylated glycerine triglycidyl ether, ethylene glycol diglycidyl ether, 1,4-butanediol diglycidyl ether, neopentyl glycol diglycidyl ether, cyclohexanedimethanol diglycidyl ether, dipropylene glycol diglycidyl ether, polypropylene glycol diglycidyl ether, dibromoneopentyl glycol diglycidyl ether, hydrogenated bisphenol A diglycidyl ether, (3,4-epoxycyclohexane) methyl 3,4-epoxycylohexylcarboxylate, and mixtures thereof.

19. The surface-metalized fiber, yarn, or fabric of claim 14, wherein said adhesive resin contains an UV radiation curable resin or lacquer selected from acrylate and methacrylate oligomers, (meth)acrylate (acrylate and methacrylate), polyhydric alcohols and their derivatives having (meth)acrylate functional groups, including ethoxylated trimethylolpropane tri(meth)acrylate, tripropylene glycol di(meth)acrylate, trimethylolpropane tri(meth)acrylate, diethylene glycol di(meth)acrylate, pentaerythritol tetra(meth)acrylate, pentaerythritol tri(meth)acrylate, dipentaerythritol hexa(meth)acrylate, 1,6-hexanediol di(meth)acrylate, or neopentyl glycol di(meth)acrylate and mixtures thereof, and acrylate and methacrylate oligomers derived from low-molecular weight polyester resin, polyether resin, epoxy resin, polyurethane resin, alkyd resin, spiroacetal resin, epoxy acrylates, polybutadiene resin, and polythiol-polyene resin.

20. The surface-metalized fiber, yarn, or fabric of claim 1, wherein said fiber is selected from a polymer fiber, glass fiber, carbon fiber, ceramic fiber, or composite fiber and said fiber yarn or fiber fabric contains multiple fibers having a fiber selected from a polymer fiber, glass fiber, carbon fiber, ceramic fiber, composite fiber, or a combination thereof.

21. The surface-metalized fiber, yarn, or fabric of claim 1, wherein said fiber contains a thermoplastic, a thermoset resin, an interpenetrating network, a rubber, a thermoplastic elastomer, a natural polymer, or a combination thereof.

22. The surface-metalized fiber, yarn, or fabric of claim 1, wherein said fiber contains a plastic selected from acrylonitrile-butadiene-styrene copolymer (ABS), styrene-acrylonitrile copolymer (SAN), polycarbonate, polyamide or nylon, polystyrene, high-impact polystyrene (HIPS), polyacrylate, polyethylene, polypropylene, polyacetal, polyester, polyether, polyether sulfone, poly ether ether ketone, poly sulfone, polyphenylene oxide (PPO), polyvinyl chloride (PVC), polyimide, polyamide imide, polyurethane, polyurea, or a combination thereof.

23. The surface-metalized fiber, yarn, or fabric of claim 1, wherein said plated metal is selected from copper, nickel, aluminum, chromium, tin, zinc, titanium, silver, gold, an alloy thereof, or a combination thereof.

24. The surface-metalized fiber, yarn, or fabric of claim 1, wherein said graphene sheets are further decorated with nanoscaled particles or coating, having a diameter or thickness from 0.5 nm to 100 nm, of a catalytic metal selected from cobalt, nickel, copper, iron, manganese, tin, zinc, lead, bismuth, silver, gold, palladium, platinum, an alloy thereof, or a combination thereof, and wherein said catalytic metal is different than said plated metal in chemical composition.

25. The surface-metalized fiber, yarn, or fabric of claim 1, wherein said graphene sheets are bonded to said surface with an adhesive resin having an adhesive-to-graphene weight ratio from 1/5000 to 1/10.

26. The surface-metalized fabric of claim 1, wherein said fabric is a non-woven web or felt, a woven material, a knit material, a braid, a netting, a macramé, a lace or a combination thereof.

27. A product containing the surface-metalized fiber, yarn, or fabric of claim 1.

28. The product of claim 27, wherein said product is selected from a vehicle component, an electrical appliance, an electronic device, a food packaging article, a protective clothing, an antistatic fabric, a blanket, an anti-reflection fabric, an EMI-shielding fabric, or a toy.

29. The product of claim 28, wherein said electric appliance or electronic device contains a wi-fi device, a cell phone, a coffee machine, a LED lamp housing, a wearable device, an electronic watch, a laptop computer, or a tablet computer.
